(19) United States
(12) Patent Application Publication
(10) Pub. No.: US 2026/0188610 A1
(43) Pub. Date: Jul. 2, 2026

(54) SCHEDULING APPARATUS, SCHEDULING METHOD, AND A NON-TRANSITORY COMPUTER READABLE MEDIUM

(71) Applicant: Hitachi High-Tech Corporation, Tokyo (JP)

(72) Inventors: Hatem Elserafy, Tokyo (JP); Kotoko Urano, Tokyo (JP); Sayaka Kurata, Tokyo (JP)

(21) Appl. No.: 19/426,566

(22) Filed: Dec. 19, 2025

(30) Foreign Application Priority Data
Dec. 26, 2024 (JP) 2024-231001

(51) Int. Cl. H01J 37/26; H01J 37/28

(52) U.S. Cl. CPC H01J 37/261; H01J 37/28; H01J 2237/216; H01J 2237/24585

(57) ABSTRACT

A scheduling apparatus for estimating time of a measurement job to be performed by a measurement apparatus includes: a memory configured to store a program; and a processor configured to perform processing in accordance with the program. The processor is configured, by executing the program, to: in response to a user inputting a measurement recipe for causing the measurement apparatus to perform the measurement job; analyze the measurement recipe and create a series of tasks on the basis of an analysis result; collect information for updating an estimation model that estimates time required for the measurement job; update the estimation model using the collected information; and input information on the series of tasks into the updated estimation model to estimate time required for the series of tasks.

### BACKGROUND

The present disclosure relates to a technique for scheduling measurements performed by a measurement apparatus.

When multiple users share an expensive measurement apparatus such as a scanning electron microscope (SEM), it is important to improve the utilization rate of the measurement apparatus. To improve the utilization rate of the measurement apparatus, users need to predict the time they will use the measurement apparatus and complete the measurement within the predicted time. However, even when a user checks the condition of the sample to be measured before measurement and understands the specifications of the measurement apparatus, it is difficult for the user to predict the time required for measurement.

U.S. Patent Application Publication No. 2020/0371126 discloses a technology for dynamically changing the instrument workflow in an instrument system having an instrument, such as a pump, and a sample chamber, such as an incubator, by optimizing an instrument workflow program that instructs the instrument and the sample chamber to operate.

### SUMMARY

After the user creates an instrument workflow program, the instrument system disclosed in U.S. Patent Application Publication No. 2020/0371126 changes the instrument workflow program so as to optimize the instrument workflow while the instrument workflow is performed. As such, there is a risk that the changed instrument workflow program may not meet the user's expectations. To have a measurement apparatus perform a job as expected by the user while improving the utilization rate of the measurement apparatus, it is important to estimate the job time more accurately.

It is an objective of the present disclosure to provide a scheduling apparatus, a scheduling method, and a program that estimate the time of a job to be performed by a measurement apparatus more accurately.

A scheduling apparatus according to one aspect of the present disclosure is a scheduling apparatus for estimating time of a measurement job to be performed by a measurement apparatus and includes: a memory configured to store a program; and a processor configured to perform processing in accordance with the program, in which the processor is configured, by executing the program, to: in response to a user inputting a measurement recipe for causing the measurement apparatus to perform the measurement job, analyze the measurement recipe and create a series of tasks on the basis of an analysis result; collect information for updating an estimation model that estimates time required for the measurement job; update the estimation model using the collected information; and input information on the series of tasks into the updated estimation model to estimate time required for the series of tasks.

According to one aspect included in the present disclosure, a user's measurement recipe is analyzed, and the time required for the measurement job is estimated by the estimation model updated using the collected information, on the basis of the series of tasks obtained by converting the measurement recipe. Thus, the measurement job is performed as desired by the user, and the measurement schedule is configured such that the operating rate of the measurement apparatus is maximized. This improves the utilization rate of the measurement apparatus.

### BRIEF DESCRIPTION OF THE DRAWINGS

FIG. 1 is a block diagram showing an example of the configuration of a scheduling apparatus according to a present embodiment;

FIG. 2 is a block diagram showing an example of the configuration of a measurement system including the scheduling apparatus according to the present embodiment;

FIG. 3 is a diagram for illustrating an example of the configuration of an information acquisition unit shown in FIG. 1;

FIG. 4 is a table showing an example of the recipe file shown in FIG. 3;

FIG. 5 is a diagram showing an example of a setting file;

FIG. 6 is a diagram for illustrating an example of samples placed on a stage of a measurement apparatus;

FIG. 7 is a table showing an example of the sample information shown in FIG. 3;

FIG. 8 is a diagram showing an example of the desired schedule shown in FIG. 3;

FIG. 9 is a diagram showing an example of other data;

FIG. 10 is a block diagram showing an example of the configuration of the information analysis unit shown in FIG. 1;

FIG. 11 is a table showing an example of a task list created by the information analysis unit;

FIG. 12 is a diagram illustrating an example of online training;

FIG. 13 is a block diagram showing an example of the configuration of the job time estimation unit shown in FIG. 1;

FIG. 14 is a block diagram showing an example of the configuration of the scheduling unit shown in FIG. 1;

FIG. 15 is a block diagram showing an example of the configuration of the report unit shown in FIG. 1;

FIG. 16 is a block diagram illustrating an example of the configuration of the error processing unit shown in FIG. 1;

FIG. 17 is a block diagram showing an example of the hardware configuration of the scheduling apparatus according to the embodiment;

FIG. 18 is a flowchart showing an example of an operation procedure of the scheduling apparatus according to the present embodiment;

FIG. 19 is a flowchart showing an example of an operation procedure of the scheduling apparatus according to the present embodiment;

FIG. 20 is a diagram showing an example of an input image displayed on an output device at step S101 shown in FIG. 18;

FIG. 21 is a diagram showing an example of an input image displayed on the output device when it is determined at step S105 shown in FIG. 18 that there is missing data;

FIG. 22 is a diagram showing an example of an input image displayed on the output device at step S110 shown in FIG. 18;

FIG. 23 is a diagram showing an example of a monitoring image in a state in which a job is in progress according to schedule; and

FIG. 24 is a diagram showing an example of a monitoring image in a state in which the progress of a job is behind schedule.

### DETAILED DESCRIPTION OF THE EMBODIMENT

The present embodiment is a scheduling apparatus that estimates the time of measurement to be performed by a measurement apparatus and creates a measurement schedule. The present embodiment is described assuming that the measurement apparatus is a scanning electron microscope (SEM), but the measurement apparatus is not limited to an SEM. An example of implementation of a scheduling apparatus of the present embodiment is described below.

### Embodiment

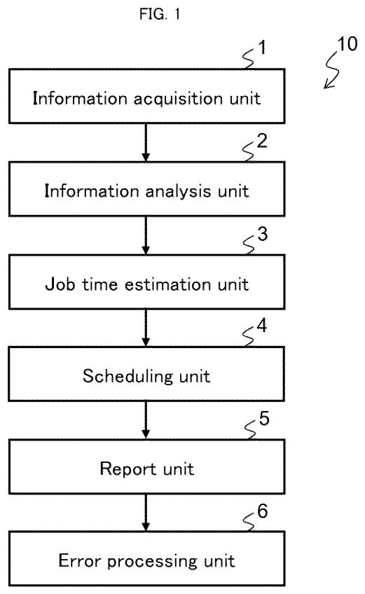

An overview of a scheduling apparatus of this embodiment is now described. FIG. 1 is a block diagram showing an example of the configuration of the scheduling apparatus according to the present embodiment. The scheduling apparatus 10 of this embodiment includes an information acquisition unit 1, an information analysis unit 2, a job time estimation unit 3, a scheduling unit 4, a report unit 5, and an error processing unit 6.

The information acquisition unit 1 receives input of job information, which is information related to a measurement job to be performed by the measurement apparatus 8, from a user. The job information includes a measurement recipe file. The job information may include sample information and other information. The measurement recipe file contains measurement conditions for one or more samples that are the measurement target. Hereinafter, the measurement recipe file is referred to as a measurement recipe or a recipe file. Also, in this embodiment, a measurement job is defined as a group of tasks that encapsulates the entire SEM measurement process. A task refers to a unit of operation that is one of multiple operations performed by the measurement apparatus 8. Hereinafter, the measurement job is simply referred to as a job. The information acquisition unit 1 also receives a desired schedule indicating the date and time when the user desires to perform the job.

The information analysis unit 2 analyzes the measurement recipe input by the user and creates a series of tasks required for the job. That is, the information analysis unit 2 converts a job into a series of tasks for measuring one or more samples according to the measurement recipe specified by the user. The job time estimation unit 3 uses machine learning (hereinafter referred to as ML) to estimate the time required for each task in the series of tasks created by the information analysis unit 2. This is because, to estimate the time required for a job, it is necessary to estimate the time required for each of a series of tasks. Hereinafter, the estimated time required for each task is referred to as estimated required time. For errors such as delays, the job time estimation unit 3 adds safety time as an appropriate safety margin to the estimated time required for a series of tasks. Hereinafter, the safety time is denoted as tw.

Upon receiving information on the estimated time required for each task from the job time estimation unit 3, the scheduling unit 4 calculates an estimated total job time, which is the sum of the received estimated required times of the tasks. Hereinafter, the total time required for one job is simply referred to as job time. The scheduling unit 4 also stores, for each of multiple users who share the measurement apparatus 8, a registered schedule indicating a schedule of expected use of the measurement apparatus 8. Based on the user's desired schedule, the scheduling unit 4 selects the most appropriate time slot from among the unscheduled time slots in the entire schedule. The scheduling unit 4 allocates the new job input by the user to the selected time slot. Then, the scheduling unit 4 stores the time slot to which the new job is allocated as a tentative schedule, which is a tentatively determined schedule. When the scheduled completion time point of a user's job is later than the start time point of another user's reserved job, the user can select one of three options. The first option is for the user to change the completion time point of the job. The second option is for the user to receive from the scheduling apparatus 10 a proposal of a recommended recipe that fits the schedule to meet the job completion time point. The third option is for the user to manually modify the measurement recipe and have the scheduling apparatus 10 reschedule the job.

The report unit 5 reports the schedule determined by the scheduling unit 4 to the user. Depending on the option selected by the user, the report unit 5 provides the user with a job time report, a recipe report, or an updated version of the measurement recipe. The job time report is to report to the user the estimated total job time and the estimated time required for each task. The recipe report is provided for user reference when a modification to the measurement recipe made by the user is not applied. The update version of the recipe is to report to the user an updated measurement recipe after a modification to the measurement recipe is applied to meet a particular deadline.

The error processing unit 6 monitors the progress of the job in real time and determines whether a delay occurs. The error processing unit 6 re-estimates the time required for the remaining tasks during the execution of the job. When the job time does not match the estimated total job time and the job needs to be terminated early, the error processing unit 6 notifies the user of a warning so that the next user's job can be started as scheduled. Examples of causes of errors include a user-based cause, an operational error in the SEM, or an incorrect estimated time required for multiple tasks or for a specific task. For example, the user-based cause may correspond to a case in which the user starts measurement later than the scheduled time. When the estimated total job time is underestimated, the error processing unit 6 prompts the user to reevaluate the recipe or proposes a new recipe. When the estimated total job time is overestimated, the error processing unit 6 gives the next user the option of starting the job earlier.

### Overall System Configuration

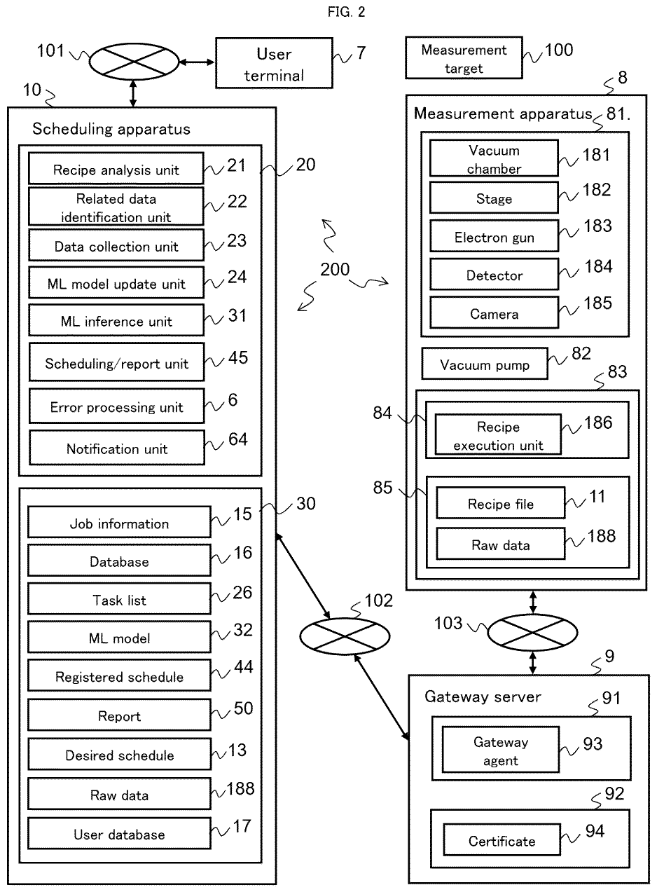

The configuration of a measurement system including the scheduling apparatus 10 of this embodiment is described. FIG. 2 is a block diagram showing an example of the configuration of a measurement system including a scheduling apparatus of the present embodiment. The measurement system 200 includes a measurement apparatus 8, a scheduling apparatus 10, and a user terminal 7. The user terminal 7 is an information processing device, such as a PC (Personal Computer) operated by a user. In this embodiment, the measurement apparatus 8 is an SEM.

A measurement target 100 is placed in the measurement apparatus 8 by the user. The user terminal 7 and the scheduling apparatus 10 are connected via an external network 101. The scheduling apparatus 10 is connected to the measurement apparatus 8 via a gateway server 9. The scheduling apparatus 10 is connected to the gateway server 9 via an external network 102. The gateway server 9 is connected to the measurement apparatus 8 via a private network 103. Referring to FIG. 2, the main configuration of each apparatus is described. Details of each apparatus are to be described below.

The measurement target 100 is a sample of a material to be measured by the measurement apparatus 8. In this embodiment, since the measurement apparatus 8 is an SEM, the measurement target 100 must be in a solid state. An example of the measurement target 100 is a silicon semiconductor wafer.

### Measurement Apparatus 8

The measurement apparatus 8 is hardware necessary for performing SEM measurement. The measurement apparatus 8 has an SEM main body 81, a vacuum pump 82, and a control computer 83. The vacuum pump 82 is necessary to generate a vacuum state suitable for SEM measurement. The control computer 83 controls the SEM main body 81 and stores control contents.

The SEM main body 81 includes a vacuum chamber 181, a stage 182, an electron gun 183, a detector 184, and a camera 185. The vacuum chamber 181 is maintained in a vacuum state so that the measurement target 100 can be observed by the SEM. The stage 182 is a platform on which the measurement target 100 is placed. The stage 182 is provided inside the vacuum chamber 181. The electron gun 183 emits electrons, causing the emitted electrons to collide with the surface of the measurement target 100. The electron gun 183 is a main part of the SEM that is used to provide a high magnification image to the user to understand the material properties of the measurement target 100. The detector 184 is used to collect the electrons generated by the electron gun 183 and bounced off the measurement target 100. The detector 184 forms a digital image of the microscope. The camera 185 provides the user with images at a lower magnification than those acquired by the SEM. The camera 185 allows the user to move the stage 182 to identify the current image-capturing location and to check that the measurement target 100 is placed at an appropriate position and that the measurement target 100 is in good condition. The present embodiment is described assuming that the SEM main body 81 includes the camera 185, but it is not necessary to provide the camera 185.

The vacuum pump 82 serves to discharge air from the vacuum chamber 181 until the pressure inside the vacuum chamber 181 reaches a predetermined vacuum level Pr0, and to maintain the pressure inside the vacuum chamber 181 at the vacuum level Pr0. This is because SEM measurement needs to be performed in a vacuum state. The required vacuum level Pr0 varies depending on the type of the measurement target 100 and the type of pump output required.

The control computer 83 controls the SEM main body 81 and stores control contents. The control computer 83 includes a processor 84, such as a CPU (Central Processing Unit), and a memory 85 for storing a program. The memory 85 is a storage apparatus used in the control computer 83 to store data. The memory 85 stores a recipe file 111 and raw data 188.

The recipe file 11 is not limited to a single measurement recipe, and may be a file including multiple measurement recipes. The recipe file 11 describes, for each sample, measurement conditions such as the number of images to be captured, the position of each image, the magnification of each image, and other setting files. The settings file is information about the settings of the SEM. The recipe file 11 may also include, regarding the raw data 188 output from the SEM main body 81, output information such as the naming method of output files, the storage location of output files, and the storage format of output files. The setting file and the output information may be files separate from the recipe file 11.

The raw data 188 is data output from the SEM main body 81. All of the output files created by the SEM main body 81 are stored in the memory 85 as raw data 188. The output of the SEM main body 81 includes an image file and a metafile corresponding to the image file. When there are multiple image files, the output of the SEM main body 81 includes a group of image files and a group of metafiles corresponding to the multiple image files.

In addition to the output of the SEM main body 81, the memory 85 stores log data of the measurement apparatus 8. For example, the log data may include temporal change of pressure in the vacuum pump 82, the time at which the vacuum chamber 181 reaches a specific vacuum level, and temporal change of the state of the SEM main body 81. The log data may also include information on the time at which a particular task, such as moving the stage 182 or autofocusing, is completed. The memory 85 may store data other than log data. The processor 84 serves as the central processing unit of the control computer 83. The processor 84 includes a recipe execution unit 186. The recipe execution unit 186 converts the recipe file 11 into a command for the SEM main body 81. The recipe execution unit 186 transmits raw data 188 and log data to the scheduling apparatus 10. The processor 84 executes a program stored in the memory 85, thereby performing the functions of the recipe execution unit 186.

### Gateway Server 9

The gateway server 9 serves to communicatively connect the control computer 83 to other apparatuses via the private network 103 and the external network 102. The gateway server 9 is provided for two purposes, namely, centralization and security. A case corresponding to the centralization purpose is now described. There may be cases in which a user uploads data to the scheduling apparatus 10 via the user terminal 7, or in which a user remotely controls the measurement apparatus 8 via the scheduling apparatus 10 while multiple apparatuses operate the measurement apparatus 8 in parallel. In such cases, connecting all of the apparatuses including the user terminal 7 to one gateway server 9 to centralize the process improves convenience for multiple users. For example, multiple apparatuses may be connected in a star-type network configuration. A case corresponding to the security purpose is now described. When the control computer 83 refuses direct connection with the external network 102 due to a security function for avoiding security risks, the gateway server 9 functions as a security gate between the control computer 83 and the external network 102. When the control computer 83 is directly connected to the external network 102 and operates on a stand-alone basis, it is not necessary to provide the gateway server 9. Stand-alone basis means that it is not a group of apparatuses operating simultaneously.

The gateway server 9 includes a processor 91, such as a CPU, and a memory 92 for storing a program. The processor 91 includes a gateway agent 93. The memory 92 contains a certificate 94. The memory 92 is a storage apparatus provided in the gateway server 9. The memory 92 serves to store the certificate 94, which authorizes access to both the memory 85 and the memory 30. The certificate 94 is a file containing the credentials required to access the memory 85 and the memory 30. The processor 91 is a central processing unit provided in the gateway server 9. The gateway agent 93 monitors the control computer 83 and, upon detecting a new recipe file 11 or new raw data 188, uploads the detected new file or data to the scheduling apparatus 10. The processor 91 executes a program stored in the memory 92, thereby performing the functions of the gateway agent 93.

### Network

The private network 103 is a network that communicatively connects the control computer 83 and the gateway server 9. The private network 103 is a network including one or both of a wired network, such as a LAN (Local Area Network) cable, and a wireless network, such as Wi-Fi (registered trademark).

The external network 102 is a network that communicatively connects the gateway server 9 and the scheduling apparatus 10. The external network 102 is a network including one or both of a wired network and a wireless network. The external network 101 is a network that communicatively connects the user terminal 7 and other information processing apparatuses with the scheduling apparatus 10. The external network 101 is a network including one or both of a wired network and a wireless network. The external network 101 and/or the external network 102 may be the Internet or a network including the Internet.

### Scheduling Apparatus 10

The scheduling apparatus 10 may be a cloud server, for example. The scheduling apparatus 10 estimates job time and schedules a job. The scheduling apparatus 10 collects data from the measurement apparatus 8 and the user terminal 7, and uses the collected data to estimate job time and schedule a job.

The scheduling apparatus 10 includes a processor 20 and a memory 30, which stores a program. The processor 20 executes the program stored in the memory 30. The memory 30 is a storage apparatus that stores information in the scheduling apparatus 10. The memory 30 stores job information 15, a database 16, a task list 26, an ML model 32, a registered schedule 44, a report 50, a desired schedule 13, raw data 188, a user database 17, and the like. The registered schedule 44 may be stored in the user database 17.

The job information 15 includes a recipe file 11 created by the user and data related to the job input by the user, such as sample information and other files. The database 16 stores, as history information, log data of the measurement apparatus 8, the reports of jobs performed in the past, the raw data of jobs performed in the past, specification data of the measurement apparatus 8, and other data. The history information includes, as training data, data combining job information and estimated total job time for jobs performed in the past. The data stored in the database 16 is used to update the ML model 32. The database 16 also stores data acquired by the data collection unit 23. The database 16 is used to assist the process of updating the ML model 32. The task list 26 is a file containing a list indicating a series of tasks created by the recipe analysis unit 21. The database 16 stores apparatus information corresponding to each of multiple vacuum pump models and apparatus information corresponding to each of multiple SEM models. When the setting file and the output information are files separate from the recipe file 11, the setting file and the output information are stored in the database 16.

The ML model 32 is an ML model file. In this embodiment, the ML model 32 is an estimation model that receives information on a series of tasks as input and outputs the estimated time required for each task. The registered schedule 44 is a calendar in which time slots of desired schedules of multiple users are registered. The time slots are reserved by the users to use the measurement apparatus 8. When the user agrees to the tentative schedule reported by the report unit 5, the registered schedule 44 is finalized and updated. In this embodiment, the registered schedule 44 is described as being in a calendar format, but is not limited to a calendar format. The report 50 is a file containing information on the estimated time required for each task, the estimated total time for the job, and the time slots scheduled by the user.

The desired schedule 13 is a file that contains the desired time frame for the user to perform the job. For example, the user can specify a deadline, which is the time point by which the job is to be completed. The user can change the deadline at any time before the deadline. In another example, the user may specify a particular time slot so that the user can freely use the measurement apparatus 8 to operate an experiment in the time slot. The scheduling apparatus 10 attempts to schedule such that the job is completed in accordance with the desired schedule. Nevertheless, if scheduling is not possible, the scheduling apparatus 10 requests a change of the deadline or a change to a different measurement recipe that corresponds to the desired schedule.

The raw data 188 is collected from the memory 85 of the control computer 83 and stored in the memory 30. This allows the scheduling apparatus 10 to track the progress of the job and determine whether the estimated time required for a particular task matches the actual time required for the task being performed. The user database 17 stores, for each user, user information collected from the user terminal 7. The user information includes the credentials required for the user to log in to the scheduling apparatus 10, an email address to which messages are sent by email from the notification unit 64, and information on schedules configured in the past, present, and future.

The processor 20 is a central processing unit in the scheduling apparatus 10. The processor 20 is used to execute the components required for scheduling and job time estimation. The processor 20 includes a recipe analysis unit 21, a related data identification unit 22, a data collection unit 23, an ML model update unit 24, an ML inference unit 31, a scheduling/report unit 45, an error processing unit 6, and a notification unit 64.

The recipe analysis unit 21 analyzes a recipe file 11, which is created by a user on the user terminal 7 and received from the user terminal 7 via the external network 101. The recipe analysis unit 21 receives the recipe file 11 as an input, creates a task list 26 as an output, and stores the task list 26 in the memory 30. The task list 26 is a list of grouped tasks required to estimate the time required for each task, which aids in job time prediction. For example, when the series of tasks is capturing an SEM image, the first task is “moving the stage from position Ps1 to position Ps2,” the second task is “autofocus,” and the third task is “capturing an image.”

The related data identification unit 22 analyzes each task and creates a list of related data necessary for the ML model 32 to estimate the time required for each task. Specifically, the related data identification unit 22 receives the task list 26 created by the recipe analysis unit 21 as an input, and creates a list of related data as an output. For example, if the task is evacuation, the related data may require “vacuum pump model” and/or “SEM model.” For example, the vacuum pump model may be a model number for identifying the manufacturer and type of the vacuum pump. For example, the SEM model may be a model number for identifying the manufacturer and type of the SEM.

The data collection unit 23 collects related data in two manners, namely, automatic collection, such as data scraping, and manual input by the user. An example of related data to be collected is described. In the following description, the data to be collected is apparatus information that is information relating to the measurement apparatus 8. For example, for sample S, after the stage 182 moves at a movement speed V and then stops, a certain waiting time tz is required before the vibration of the stage 182 is damped. Image capture is suspended until the vibration of the stage 182 is damped because the vibration of the stage 182 causes the captured image to be out of focus and blurred. In this case, the apparatus information includes the autofocus speed, the stage movement speed V, and the damping time tz, which is the waiting time for stage vibration. When the material of the sample that is the measurement target 100 is a new material, the damping time tz is preferably determined according to advice of an expert studying the target material. The advice of an expert may be acquired by the Delphi method, for example. The data collected by the data collection unit 23 is stored in the database 16.

To cause the ML model 32 to estimate the time required for each task in the series of tasks, the ML model update unit 24 inputs the task list 26 and related data into the ML model 32 and updates the ML model 32. Also, the ML model update unit 24 may train the ML model 32 using the log data stored in the database 16. The ML inference unit 31 executes the ML model 32 to estimate the job time. The ML inference unit 31 adds an appropriate safety time tw as a safety margin to the estimated time required for a series of tasks in anticipation of the occurrence of an error, such as a delay.

The scheduling/report unit 45 includes the scheduling unit 4 and the report unit 5 shown in FIG. 1. Upon receiving information on the predicted time required for each task and the safety time tw from ML inference unit 31, the scheduling/report unit 45 calculates estimate total job time, which is the total value of the received predicted time required for each task. The scheduling/report unit 45 writes both the predicted time required for each task and the estimated total job time into a report 50 and stores a draft of the report 50 in the memory 30. The scheduling/report unit 45 refers to the registered schedule 44 to search for available time slots on the basis of the user's desired schedule 13. When a free time slot is found as a result of the search, the scheduling/report unit 45 allocates the user's job to the free slot. Once the user agrees to the scheduled time slot, the scheduling/report unit 45 writes the scheduled time slot into the report 50. The report 50 is updated after the user agrees to the tentative schedule. When the user does not agree to the tentative schedule, the user can change the desired schedule 13, manually modify the recipe, or request the scheduling apparatus 10 to propose a recipe.

The error processing unit 6 checks the time point at which the raw data 188 was created, and compares the actual time required from the start of the job to the task being performed with the estimated time required from the start of the job to the task being performed. The error processing unit 6 determines whether these times match. When the result of comparison indicates that the two times do not match, the error processing unit 6 performs error handling processing. When the estimated total job time is overestimated, the job ends before the completion time point of its scheduled time slot. As such, the error processing unit 6 notifies the user who has reserved the next time slot that the job can be started earlier. The notification method may be email, for example. In contrast, when the result of comparison indicates that the estimated total job time is underestimated, the schedule of the job being performed conflicts with the schedule of the next user's job. Thus, the job being performed needs to be terminated earlier. In this case, the error processing unit 6 notifies the user of a warning. When the user is notified of the warning, the user may abandon the task at the end in the chronological order of the task list 26, or, when there is sufficient time, select the task to be performed within the limited time and the task to be abandoned.

When the start time point of the next job approaches, the notification unit 64 sends a reminder to the user to prompt preparation. Furthermore, when the job of the previous user is completed earlier than planned, the notification unit 64 notifies the next user that there is an option to start the job earlier. When the progress of the job is delayed, the notification unit 64 warns the user that action is required to address the delay. Notification to the user may be made via email or other communication means.

### Others

The configuration shown in FIG. 2 is an example. In another example, the control computer 83 may have the configuration of the scheduling apparatus 10 and perform the functions of the scheduling apparatus 10. In this case, it is not necessary to provide the user terminal 7, the scheduling apparatus 10, the gateway server 9, the external networks 101 and 102, and the private network 103. The configuration of the measurement system 200 is not limited to the configuration shown in FIG. 2.

### Scheduling Apparatus 10

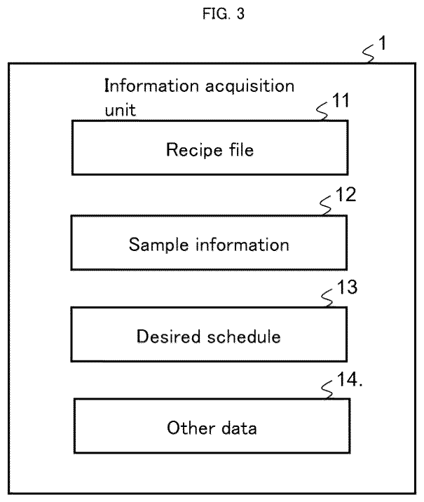

Referring to FIGS. 3 to 16, each component of the scheduling apparatus 10 shown in FIG. 1 is now described in detail.

### Information Acquisition Unit 1

The configuration of the information acquisition unit 1 shown in FIG. 1 is described. FIG. 3 is a diagram for illustrating an example of the configuration of the information acquisition unit shown in FIG. 1. The information acquisition unit 1 receives, from the user, input of job-related information, such as measurement recipe information including a recipe file 11, sample information 12, and information related to other settings. The information acquisition unit 1 receives input of a desired schedule 13 from the user.

### Recipe File

The recipe file 11 is now described. When the user uploads a recipe file 11 for analysis, the recipe analysis unit 21 converts the recipe file 11 into a task list 26, and the task list 26 is stored in the memory 30. The recipe file 11 may have a variety of forms depending on the model of the measurement apparatus 8 or the interaction between the control computer 83 and the SEM main body 81.

An example of the recipe file 11 is now described. The recipe file 11 is a csv file that includes the number of images, two-dimensional coordinates (X, Y) that specify the position of each image on the stage 182, the magnification (zoom) of each image, and other measurement conditions. Also, when multiple samples are mounted on the same substrate, such as a board, the recipe file 11 may include information indicating a sample or specimen to which the target to be imaged belongs. Additionally, the recipe file 11 may have a txt file that includes the naming system for each image, the location where each image is stored, and the format of each image. This txt file is referred to as a setting file and is described below.

When a job involves acquiring images of multiple samples, the recipe file 11 is complicated. To acquire images of multiple samples, such a recipe file 11 additionally includes the acquisition of low-magnification images to determine that the area of the multiple samples is clean, and stage vibration damping time for each of the multiple samples. The low-magnification images are acquired by the camera 185. In this case, it is desirable to increase the safety time tw added to the estimated time required for a series of tasks including the acquisition of low-magnification images and multiple instances of stage vibration damping. In this manner, by adding the safety time tw, which is a safety margin of error, to the estimated time required for a series of tasks in accordance with the contents of the recipe file 11, the job is less likely to be forcibly terminated midway due a minor operational error.

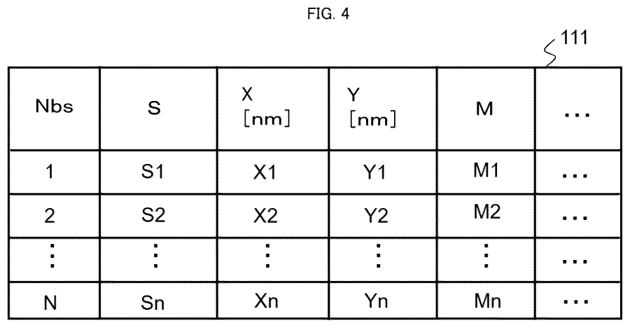

Referring to FIG. 4, a specific example of the recipe file 11 is described. FIG. 4 is a table showing an example of the recipe file shown in FIG. 3. A recipe file 111 shown in FIG. 4 is an example of the recipe file 11. As shown in the recipe file 111, the number N of images acquired from n samples in one job and the acquisition method for each image are registered in a table format. In the table shown in FIG. 4, each image is identified by row, and the acquisition method for each image, such as the two-dimensional coordinates on the stage 182, the magnification, and other setting information, is identified by column. The recipe file 111 may be a csv file. In the example shown in FIG. 4, Nbs is a sample ID, which is an identifier that is different for each sample. S is the sample name, X is the X coordinate on the stage, Y is the Y coordinate on the stage, and M is the magnification. Although FIG. 4 shows a measurement recipe for one user, measurement recipes for multiple users may be registered in one file as long as the measurement recipe for each user can be identified.

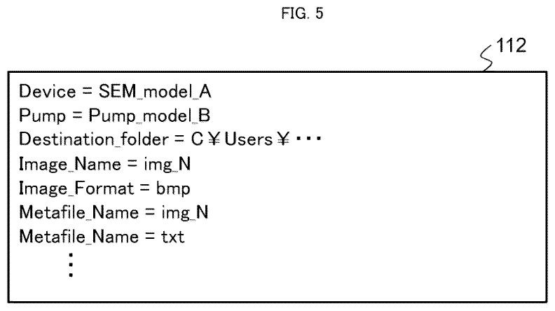

FIG. 5 is a diagram showing an example of a setting file. The setting file 112 may be a part of the recipe file 11 or may be a file separate from the recipe file 11. The setting file 112 is an example of setting information. The setting file 112 contains the SEM model, the vacuum pump model, the location of the data storage folder, the image naming method, the image data format, the image and metafile naming method, and other information. In FIG. 5, “Device” represents the SEM model, “Pump” represents the vacuum pump model, and “Destination_folder” indicates the location of the data storage folder. “Image_Name” indicates the naming method of the image, and “Image_Format” indicates the data format of the image. “Metafile_Name” indicates the image and metafile naming method. For example, the first image has a file name img_1.bmp, and the metafile corresponding to this image has a file name img_1.txt.

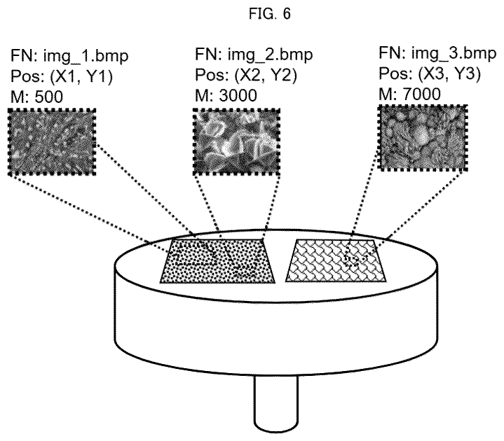

FIG. 6 is a diagram for illustrating an example of samples placed on the stage of the measurement apparatus. The number of samples measured in one job may be one, but is not limited to one. FIG. 6 shows a state in which two samples are placed on the stage 182. In this case, the measurement recipe is to acquire three images from the two samples, for example. Of the three images, two are images of sample 1 and the other one is an image of sample 2. Two-dimensional coordinates specifying the position and the magnification are configured for each of the three images. For the three measurement locations shown in FIG. 6, the file name is represented as FN, the two-dimensional coordinates are represented as Pos, and the magnification is represented as M. As shown in FIG. 6, one job may measure multiple samples. FIG. 6 is an example for illustrating a case in which multiple samples are placed on the stage 182, and the number of samples is not limited to two and may be three or more.

### Sample Information

The sample information 12 shown in FIG. 3 is described. When a user uploads information about a sample, such as the type of material, the size, weight, and manufacturing method of the sample, as sample information 12, the sample information 12 is stored in the memory 30. The sample information 12 is useful in estimating the time required for certain tasks, such as moving the stage 182, damping of vibration of the stage 182, and autofocusing. The sample information is written in a csv file, for example. When sample information is registered in a table format, each column represents a specific property of the sample, such as sample name, material composition, heat treatment temperature, manufacturer, and the like, and each row represents a different sample. By preparing sample information 12, multiple samples can be mounted on the stage 182, and images of multiple samples can be captured in one job.

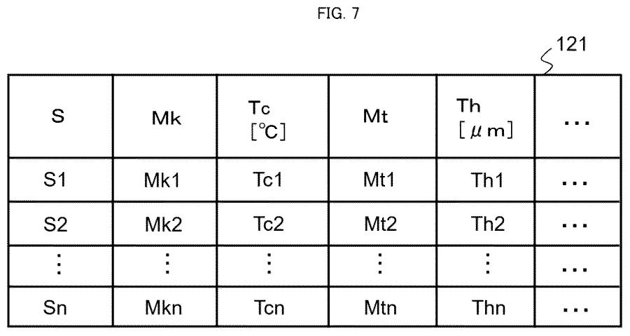

Referring to FIG. 7, a specific example of sample information 12 is described. FIG. 7 is a table showing an example of the sample information shown in FIG. 3. In a sample information file 121 shown in FIG. 7, each row represents a sample, and each column represents an attribute such as the manufacturing method of the sample, sample properties, and manufacturer. The sample information file 121 is not limited to a table format, and may be a csv file, for example. The sample S or sample ID is a required item, but the remaining items can be flexibly configured by the user. In the example shown in FIG. 7, Mk is the manufacturer's name, Tc is the heat treatment temperature to which the sample is heated during the manufacturing process, Mt is the material composition of the sample, and Th is the thickness of the material (when the sample is in film form). The material may be TiO or TiO₂, for example. Other information such as specimen weight may be added to the items of the sample information 12.

### Desired Schedule

The desired schedule 13 shown in FIG. 3 is described. The desired schedule 13 is input to the information acquisition unit 1 by the user. The desired schedule 13 is a date and time at which a user desires a job to be performed. One example of a method for inputting the desired schedule 13 is the user inputting a desired start date and time or a desired end date and time for the job. Once the desired schedule 13 is accepted, the user can manipulate the schedule of this job at any time before the desired schedule 13 is completed. Another input method is the user inputting a desired time slot (start date and time point to end date and time point). When the information acquisition unit 1 receives one or more desired schedules 13 from multiple users, it stores the received desired schedules 13 in the memory 30.

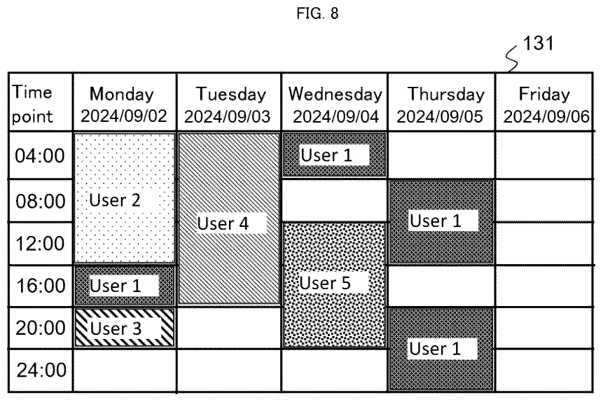

FIG. 8 is a diagram showing an example of the desired schedule shown in FIG. 3. FIG. 8 shows a calendar 131 in which desired schedules 13 are input. The calendar 131 contains desired schedules 13 input by multiple users. The same user may input multiple desired schedules 13 into the calendar 131. A user can input a desired schedule 13 into the calendar 131. The example shown in FIG. 8 is a case in which user 1 has input multiple desired schedules. In the example shown in FIG. 8, user 1 is the user currently inputting desired schedules. Users 2 to 5 are other users whose time slots are scheduled before user 1. User 1 may, not only directly inputting a desired schedule 13 into the calendar 131, but also input a desired schedule 13 by configuring a deadline for a desired schedule 13 or by configuring a group of multiple time slots in which the user is available. The calendar 131 is stored in the user database 17.

In the example shown in FIG. 8, four desired schedules 13 are input by user 1. The first time slot is from 16:00 to 20:00 on 2024/09/02. The second time slot is from 04:00 to 08:00 on 2024/09/04. The third time slot is from 08:00 to 16:00 on 2024/09/05. The fourth time slot is from 20:00 to 24:00 on 2024/09/05. In this example, the deadline for user 1 to operate the job is Thursday.

### Other Data

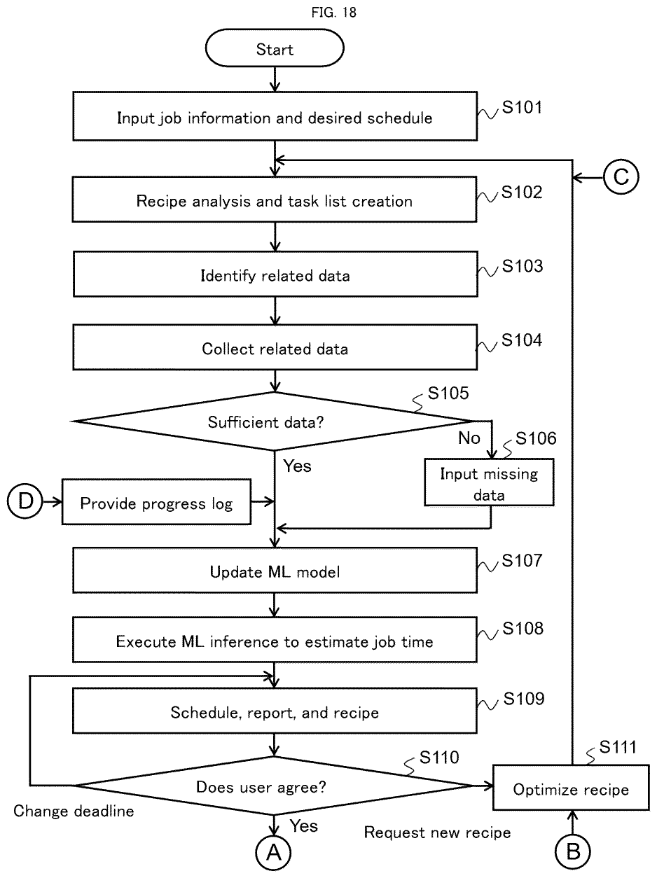

The other data 14 shown in FIG. 3 is described. When the data collected in the memory 30 is not sufficient to create a task list 26 or to estimate a job time, the user inputs other data 14 (see step S106 of FIG. 18). In one example, when the measurement target 100 is a new material, other data 14 includes autofocus time and stage vibration damping time tz. For a new SEM model, other data 14 includes stage vibration damping time tz and the like.

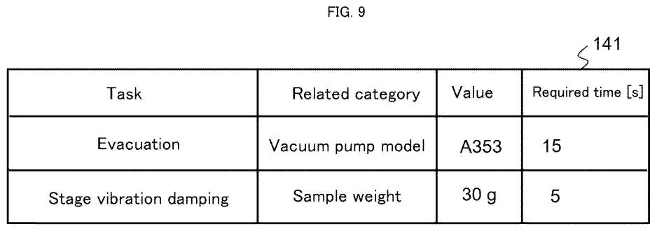

FIG. 9 is a diagram showing an example of other data 14. Table 141 shown in FIG. 9 indicates additional data required to estimate the time required for the task. In table 141, each row indicates a type of additional data. The first column of table 141 indicates the task. The second column of table 141 indicates the related category. The related category corresponds to a missing factor that is highly correlated with the task. The third column of table 141 is the value that the user is prompted to input. The fourth column of table 141 is the required time (in seconds). In the required time column, the user inputs the time required for the task on the basis of past experience. For example, when the first task of evacuation uses a new vacuum pump, the apparatus information of the vacuum pump model may not be registered in the database 16. In this case, the job time estimation unit 3 cannot estimate the time required for evacuation. The user is therefore prompted to input the time required for evacuation. The second task is stage vibration damping. When the user has not input the sample weight in the sample information, the user is prompted to input both a value for the sample weight and estimated damping time of stage vibration. In this manner, missing data is supplemented as a preprocessing step before estimating the job time.

### Information Analysis Unit 2

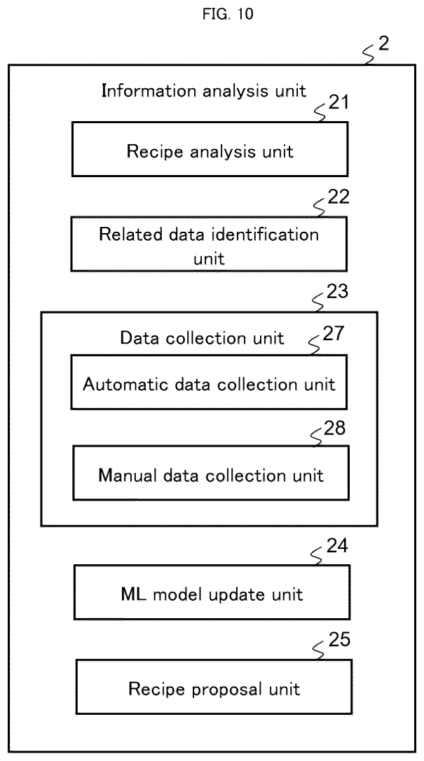

The configuration of the information analysis unit 2 shown in FIG. 1 is described. FIG. 10 is a block diagram showing an example of the configuration of the information analysis unit shown in FIG. 1. The information analysis unit 2 analyzes the recipe file 11 input by the user and identifies a series of tasks required for the job. The information analysis unit 2 creates a series of tasks required to estimate the job time. The information analysis unit 2 includes a recipe analysis unit 21, a related data identification unit 22, a data collection unit 23, an ML model update unit 24, and a recipe proposal unit 25.

The recipe analysis unit 21 receives a recipe file 11 created by a user from the user terminal 7 via the external network 101 and analyzes the received recipe file 11. The recipe analysis unit 21 receives the recipe file 11 as an input, creates a task list 26 as an output, and stores the task list 26 in the memory 30. The task list 26 is a list of grouped tasks, and the time required for each task needs to be estimated to estimate the job time. For example, when the series of tasks is capturing an SEM image, the first task is “moving the stage from position Ps1 to position Ps2,” the second task is “autofocus,” and the third task is “capturing an image.”

Furthermore, when one job involves multiple samples, the autofocus time may differ between the multiple samples. Accordingly, when there are two samples, the recipe analysis unit 21 creates two tasks with different names as the tasks of capturing sample images, instead of using tasks with the same name for the two samples. For example, the recipe analysis unit 21 names one of the two tasks “AF_sample1” and the other task “AF_sample2.”

In one example of recipe analysis, the user may create a measurement recipe according to a specific recipe file format, and the processor 20 may execute a program that performs the functions of a recipe reader. In another example of recipe analysis, when the user is not familiar with a predetermined input format, the recipe analysis unit 21 may be configured to analyze a measurement recipe input by the user in natural language.

The related data identification unit 22 analyzes each task in the task list 26 created by the recipe analysis unit 21, and creates and outputs a list of related data required to create a series of tasks. The related data identification unit 22 receives the task list 26 created by the recipe analysis unit 21 as an input, and creates and outputs a list of related data. For example, for an evacuation task, the related data includes “vacuum pump model,” “SEM model,” “chamber size,” and the like. In this manner, as preprocessing before job time estimation, the related data identification unit 22 classifies data and performs filtering to extract data necessary for the estimation process.

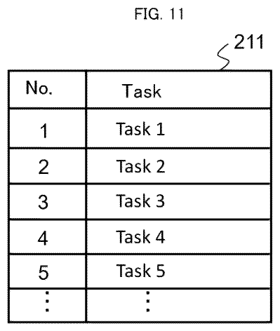

An example of the task list 26 is now described. FIG. 11 is a table showing an example of a task list created by the information analysis unit. In the task list 211 shown in FIG. 11, each row represents a task, the first column represents the task number, and the second column represents the task itself. Specific examples of tasks 1 to 5 are described.

Task 1 is evacuation by the vacuum pump 82. The purpose of task 1 is to discharge air from the vacuum chamber 181 in preparation for measurement. Task 2 is to move the stage 182. The purpose of task 2 is to configure accurate two-dimensional coordinates with respect to the stage 182 so that the sample is irradiated with electrons from the electron gun 183. Task 3 is to dampen the vibration of the stage 182. The purpose of task 3 is to limit blurring of the image of the sample due to vibration of the stage 182. Task 4 is to control autofocus, auto brightness adjustment, and auto contrast adjustment. Task 5 is to capture an image of the sample. These tasks are highly dependent on the measurement recipe.

The data collection unit 23 serves to collect the related data of the list output from the related data identification unit 22. Some of the related data may be in the database 16. In this case, the data collection unit 23 acquires the related data from the database 16. Other related data not stored in the database 16 needs to be collected. The data collection unit 23 is functionally divided into an automatic data collection unit 27 and a manual data collection unit 28 depending on the collection process. For example, after the stage 182 carrying the sample S moves at a movement speed V and then stops, a certain waiting time is required before the vibration of the stage is damped. When the sample S is a new material, the data necessary to estimate the waiting time is preferably acquired with advice of an expert studying the new material. The manual data collection unit 28 receives input of the waiting time predicted by the user who has obtained advice from an expert of the material. The collected data is stored in the database 16. The automatic data collection unit 27 automatically performs data scraping. This data scraping involves scraping data from the database 16. In one example of another automatic collection method, the automatic data collection unit 27 may use web scraping to collect data that is not stored in the database 16 via the external network 101 including the Internet. In this manner, the missing data required to estimate the job time is supplemented.

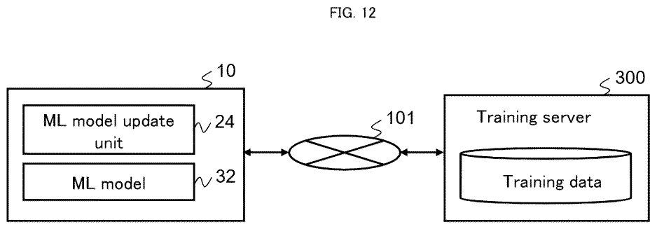

The ML model update unit 24 trains the ML model 32 on the basis of the output of the recipe analysis unit 21, related data, and data stored in the database 16. Also, the ML model update unit 24 may be coupled to an external server via the external network 101 and perform online training to train the ML model 32 using the external server. FIG. 12 is a diagram illustrating an example of online training. The scheduling apparatus 10 is coupled to a training server 300 via an external network 101. The training server 300 stores a large amount of training data for training the ML model 32. For example, the training data may be combination data of sample information and estimated total time for a measurement job for a new material that has not been measured by the measurement apparatus 8. The training data may also be combination data of apparatus information and estimated total job time for a newly released SEM model or vacuum pump. The ML model update unit 24 acquires a large amount of training data from the training server 300 via the external network 101. The ML model update unit 24 trains the ML model 32 using the large amount of acquired training data. This improves the accuracy of the estimated time required for each task, which is estimated by the job time estimation unit 3.

The recipe proposal unit 25 analyzes a job time report, which is described below, the user's desired schedule 13, and the desired schedules of other users stored in the user database 17. For the job in progress, the analysis target may include the log data of the measurement apparatus 8. As a result of analyzing these data, the recipe proposal unit 25 proposes a recipe that satisfies the user's desired schedule 13. Specifically, the recipe proposal unit 25 determines how much the job time needs to be shortened to meet the user's desired schedule 13. Then, the recipe proposal unit 25 assigns a different weight to each of the multiple tasks, modifies the recipe so as to shorten the total time, and proposes the modified recipe to the user. The recipe proposal unit 25 assigns a larger weight to a task with greater importance.

For example, a case is assumed in which, as specific continuous tasks such as image capturing, a task of image capturing is repeated 50 times at different locations close to each other within a certain area for redundancy and anomaly avoidance. It is assumed that the time required for one task is one minute. Consider a case in which the schedule calendar has a free time slot that matches the user's desired schedule 13, but this free time slot is five minutes shorter than the estimated time required for the particular continuous tasks. In this case, the recipe proposal unit 25 proposes to the user a recipe in which the task is repeated 45 times. The proposed recipe has five fewer tasks than the recipe with 50 tasks, so that the time required for the continuous tasks is reduced by five minutes. This allows the job to be accommodated within the user's desired schedule 13.

The recipe proposal unit 25 may also propose to the user a recipe in which, of the 50 tasks, a high weight is assigned to the first ten tasks, an intermediate weight is assigned to the next 30 tasks, and a low weight is assigned to the remaining ten tasks. Since the last ten tasks have a low weight, discarding five of the last ten tasks to complete the job in the user's desired schedule 13 will have a low impact on the objective of the recipe. The user can select whether to agree to the recipe proposed by the recipe proposal unit 25 (see step S110 in FIG. 18).

### Job Time Estimation Unit 3

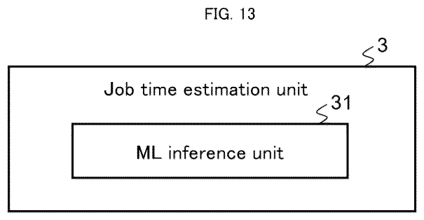

The configuration of the job time estimation unit 3 shown in FIG. 1 is described. FIG. 13 is a block diagram showing an example of the configuration of the job time estimation unit shown in FIG. 1. The job time estimation unit 3 uses ML to estimate the time required for each task in the task list 26 created by the information analysis unit 2. Also, in anticipation of the occurrence of an error, the job time estimation unit 3 adds an appropriate safety time tw to the estimated time required for a series of tasks. The job time estimation unit 3 includes an ML inference unit 31.

The ML inference unit 31 inputs information on a series of tasks into the ML model 32, which is stored in the memory 30 and updated by the ML model update unit 24, and causes the ML model 32 to output information on the predicted time required for each task. Furthermore, the ML inference unit 31 determines a safety time tw, which is a safety margin for the time required for a series of tasks. The information on the safety time tw serves as a criterion for determining the estimation accuracy. A shorter safety time tw indicates a higher estimation accuracy.

### Scheduling Unit 4

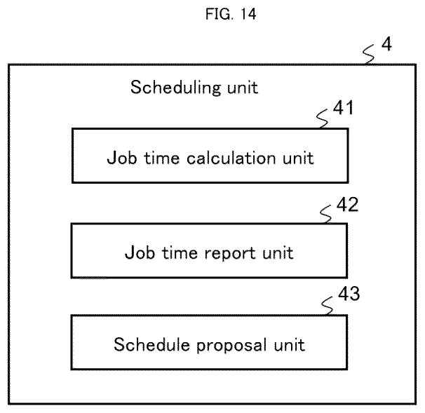

The configuration of the scheduling unit 4 shown in FIG. 1 is described. FIG. 14 is a block diagram illustrating an example of the configuration of a scheduling unit shown in FIG. 1. The scheduling unit 4 forms a part of the scheduling/report unit 45. Upon receiving information on the predicted time required for each task from the job time estimation unit 3, the scheduling unit 4 calculates an estimated total job time, which is the sum of the received predicted time required for each task. The scheduling unit 4 causes the memory 30 to store, for each of multiple users who share the measurement apparatus 8, a registered schedule 44 indicating the schedule of expected use of the measurement apparatus 8. Based on the user's desired schedule 13, the scheduling unit 4 selects the most appropriate time slot from the unscheduled time slots in the entire schedule. The scheduling unit 4 allocates the new job input by the user to the selected time slot.

When the scheduled completion time point of the user's job is later than the start time point of another user's reserved job, the user can select one of three options. The first option is for the user to change the completion time point of the job. The second option is for the user to request the recipe proposal unit 25 to propose a recommended recipe that fits the schedule so as to meet the job completion time point (see step S111 in FIG. 18). The third option is for the user to manually modify the measurement recipe and have the scheduling apparatus 10 reschedule the job. The scheduling unit 4 includes a job time calculation unit 41, a job time report unit 42, and a schedule proposal unit 43.

The job time calculation unit 41 obtains the estimated total job time by adding up the estimated time required for each task of a series of tasks. The job time report unit 42 creates a job time report including the output information of the job time estimation unit 3 and the job time calculation unit 41. Specifically, the job time report unit 42 creates, as an example of the report 50, a job time report that includes both the estimated time required for each task and the estimated total job time. The purpose of the job time report unit 42 is to present a job time report to the user after the schedule proposal unit 43 creates a tentative schedule. When the user does not agree to the tentative schedule and considers modifying the recipe, the user can check the job time report to know the estimated time required for each task.

The schedule proposal unit 43 collects user information including the user's past schedule from the user database 17. Based on the user information and the desired schedules of multiple users stored in the registered schedule 44, the schedule proposal unit 43 proposes to the user a tentative schedule allocated to a free time slot. The user can select to agree to the proposed tentative schedule, manually modify the recipe, request a recommended recipe, or change the desired schedule 13. When the user finalizes the job schedule and measurement recipe, the schedule proposal unit 43 transmits information on the schedule and measurement recipe to the control computer 83. The schedule includes information on the start date and time and the end date and time of the measurement recipe.

### Report Unit 5

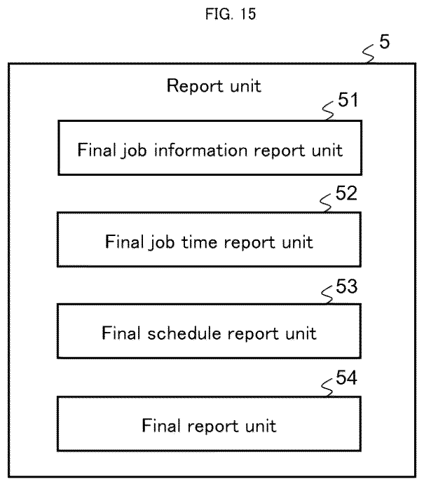

The configuration of the report unit 5 shown in FIG. 1 is described. FIG. 15 is a block diagram showing an example of the configuration of the report unit shown in FIG. 1. The report unit 5 forms a part of the scheduling/report unit 45. The report unit 5 serves to report the schedule determined by the scheduling unit 4 to the user. The report unit 5 operates when the user checks the schedule presented by the schedule proposal unit 43. Depending on the option selected by the user, the report unit 5 provides the user with a job time report, a recipe report, or an updated version of the measurement recipe. The job time report is to report to the user the estimated total job time and the estimated time required for each task. The recipe report is provided for user reference when a modification to the measurement recipe made by the user is not applied. The update version of the recipe is to report to the user an updated measurement recipe after a modification to the measurement recipe is applied to meet a particular deadline. The report unit 5 includes a final job information report unit 51, a final job time report unit 52, a final schedule report unit 53, and a final report unit 54.

The final job information report unit 51 creates a final job information report including job information 15 and sample information 12. When the measurement recipe is updated to match the desired schedule 13, the job information 15 includes both the old version and the new version.

The final job time report unit 52 creates a final job time report, which is the final version of the job time report created by the job time report unit 42. The job time report created by the job time report unit 42 is merely a draft that needs to be revised or reviewed. Thus, after the user checks the registered schedule 44 proposed by the scheduling apparatus 10, a final job time report is needed.

The final schedule report unit 53 creates a final schedule report, which is the final version of the schedule report that reports the finalized schedule. In the final schedule report, the final schedule report unit 53 may notify the user that unless the user starts the job early, the entire job may not be completed, for example.

The final report unit 54 provides the user with a final report that combines the final job information report, the final job time report, and the final schedule report into one file. In one example of a method of providing the final report, the final report unit 54 transmits the final report to the user terminal 7 of the user via the notification unit 64 using a communication means such as email. When the user selects to approve the tentative schedule proposed by the schedule proposal unit 43, the final report unit 54 creates a final report after the user approves the tentative schedule.

### Error Processing Unit 6

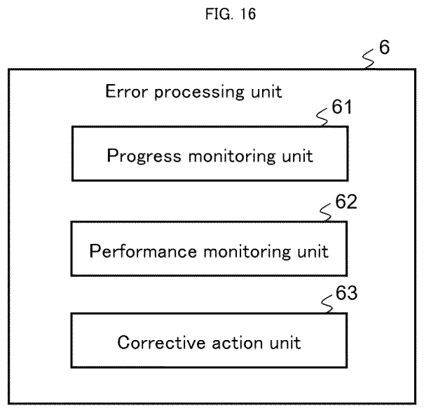

The configuration of the error processing unit 6 shown in FIG. 1 is described. FIG. 16 is a block diagram illustrating an example of the configuration of the error processing unit shown in FIG. 1. The error processing unit 6 monitors the progress of the job in real time, analyzes the progress of the job in real time at a predetermined timing, determines whether there is a delay, and estimates the time required for the remaining tasks. The predetermined timing may be a fixed cycle or when a task is switched, for example. The error processing unit 6 receives information on the estimated time required for each task, the estimated total job time, and the safety time tw from the scheduling unit 4.

The error processing unit 6 compares the time required for the remaining tasks of the job with the estimated required time. When the comparison result indicates that the time required for the remaining job is longer than the estimated required time, the error processing unit 6 determines that the job needs to be finished earlier than scheduled. In this case, the error processing unit 6 notifies the user of a warning so that the next user's job can be started as scheduled. The causes of errors include a user-based cause, an operational error in the SEM, or an incorrect estimated time required for multiple tasks or for a specific task. For example, the user-based cause may correspond to a case in which the user starts measurement later than the scheduled time. When the estimated total job time is underestimated, the error processing unit 6 prompts the user to reevaluate the recipe or proposes a new recipe to the user. In contrast, when the estimated total job time is overestimated, the error processing unit 6 provides the next user with the option of starting the job earlier.

The error processing unit 6 includes a progress monitoring unit 61, a performance monitoring unit 62, and a corrective action unit 63. The progress monitoring unit 61 examines log data relating to measurement, such as the state of the SEM main body 81, and timestamps for the creation of images and metafiles. The log data helps the progress monitoring unit 61 to identify which task in the task list is currently being performed. The progress monitoring unit 61 tracks the progress of the job in real time based on the log data received from the measurement apparatus 8.

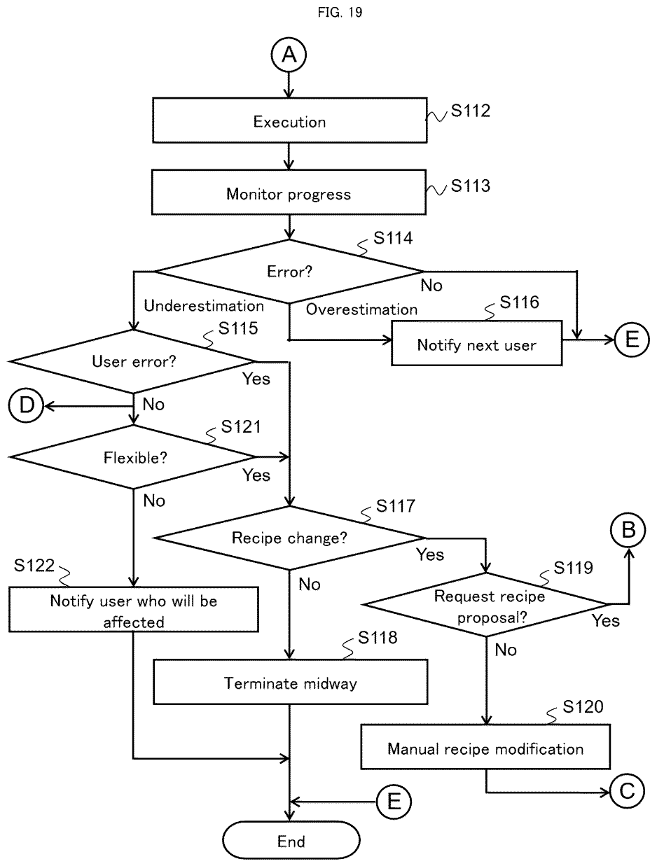

Based on the progress determined by the progress monitoring unit 61, the performance monitoring unit 62 calculates the actual time required from the start of the job to the task currently being performed, and compares the calculated required time with the required time estimated by the ML inference unit 31 (see step S114 shown in FIG. 19). This is described in detail below. The performance monitoring unit 62 receives the monitoring result from the progress monitoring unit 61, and calculates the time required for the completed tasks on the basis of the monitoring result. This value is the actual time required from the start of the job to the task currently being performed. The actual required time is denoted as tr. Then, the performance monitoring unit 62 compares the determined actual required time tr with the estimated required time on the basis of the report created by the final job time report unit 52. The estimated time required from the start of the job to the task currently being performed is denoted as tp.

Also, the performance monitoring unit 62 determines an allowable time tm, which is a margin time shorter than the safety time, for the difference between the actual required time tr and the estimated required time tp. For example, the allowable time tm may be 10% of the time of the entire job. Then, the performance monitoring unit 62 determines whether the actual required time tr is longer or shorter than the estimated required time tp. The performance monitoring unit 62 also determines whether the difference between the actual required time tr and the estimated required time tp is equal to or smaller than the safety time tw. Through this determination process, the performance monitoring unit 62 outputs four different results. An example of four different results is described below.

The first output corresponds to a case in which the difference between the estimated required time tp and the actual required time tr is equal to or smaller than the allowable time tm. That is, the first output corresponds to a case in which |tp−tr|≤tm.

The second output corresponds to a case in which the estimated required time tp is longer than the actual required time tr, and the difference between the estimated required time tp and the actual required time tr is greater than the allowable time tm. That is, the second output corresponds to a case in which tm<tp−tr.

The third output corresponds to a case in which the estimated required time tp is shorter than the actual required time tr, and the difference between the estimated required time tp and the actual required time tr is equal to or smaller than the safety time tw. That is, the third output corresponds to a case in which 0<tr−tp≤tw.

The fourth output corresponds to a case in which the estimated required time tp is shorter than the actual required time tr, and the difference between the estimated required time tp and the actual required time tr is greater than the safety time tw. That is, the fourth output corresponds to a case in which 0<tr−tp>tw.

A specific example of the four outputs of the performance monitoring unit 62 is described. To simplify the description, it is assumed that the job includes ten tasks, namely, task 1 to task 10, the processing of the ML model takes 1 minute for each task, and the safety time tw is 5 minutes. In this case, the estimated total time for the job is 15 minutes, including the safety time tw. In other words, 10 minutes (=1 minute×number of tasks)+tw=15 minutes. The allowable time tm is set to 10% of the total job time. In other words, tm=1 minute. It is assumed that the job starts at 10:00, tasks 1 to 4 have been completed, and task 5 is currently being performed. That is, the current time point is approximately 10:05.

Under the above assumption, when the current time point is 10:04, 10:05, or 10:06, the output of the performance monitoring unit 62 is the first output among the four outputs described above.

When the current time point is 10:03, the output of the performance monitoring unit 62 is the second output among the four outputs.

When the current time point is 10:08, the output of the performance monitoring unit 62 is the third output among the four outputs. This is because the delay is 3 minutes, which is shorter than the safety time tw (=5 minutes).

When the current time point is 10:11, the output of the performance monitoring unit 62 is the fourth output among the four outputs. This is because the delay is 6 minutes, which is longer than the safety time tw (=5 minutes).

Based on the output of the performance monitoring unit 62, the corrective action unit 63 determines whether corrective action is necessary. When determining that corrective action is necessary, the corrective action unit 63 determines an optimum corrective action. The operation of the corrective action unit 63 in a case in which the output of the performance monitoring unit 62 is the first output is described. The first output corresponds to a case in which the difference between the estimated required time tp and the actual required time tr is equal to or smaller than the allowable time tm. In this case, the corrective action unit 63 determines that no corrective action is necessary.

The operation of the corrective action unit 63 in a case in which the output of the performance monitoring unit 62 is the second output is described. The second output corresponds to a case in which the estimated required time tp is longer than the actual required time tr. In this case, the corrective action unit 63 provides feedback to the information analysis unit 2 indicating that the estimated required time tp is longer than the actual required time tr. The ML model update unit 24 performs online training on the ML model 32 to improve the accuracy of the ML model 32. When the above situation continues until the end of the job, the corrective action unit 63 sends a notification to the next user via the notification unit 64, offering the next user the option to start the job earlier than the reserved time.

The operation of the corrective action unit 63 in a case in which the output of the performance monitoring unit 62 is the third output is described. The third output corresponds to a case in which the estimated required time tp is shorter than the actual required time tr, and the difference between them is equal to or smaller than the safety time tw. In this case, the corrective action unit 63 provides feedback to the information analysis unit 2 indicating that the estimated required time tp is shorter than the actual required time tr and that the time difference is equal to or smaller than the safety time tw, so as to prompt online training for improving the accuracy of the ML model 32. The corrective action unit 63 then sends a notification to the user of the job being performed via the notification unit 64, warning that the job is running slower than expected. In this case, although the user can make a recipe modify for the remaining tasks that is considered necessary, the user does not have to do anything about this warning because the delay is within the safety time tw.

The operation of the corrective action unit 63 in a case in which the output of the performance monitoring unit 62 is the fourth output is described. The fourth output corresponds to a case in which the estimated required time tp is shorter than the actual required time tr and the difference between these times is greater than the safety time tw. In this case, the corrective action unit 63 provides feedback to the information analysis unit 2 indicating that the estimated required time tp is shorter than the actual required time tr and that the time difference between these times is greater than the safety time tw, so as to prompt online training for improving the accuracy of the ML model 32. Furthermore, the corrective action unit 63 determines whether the delay is due to an external cause or an internal cause. An external cause is a case in which the user is responsible, such as when the user delays starting preparations for sample measurement. An internal cause is a case in which the user is not responsible, such as when the ML model underestimates the time required for a task.

When the user is responsible for the cause of the delay, the corrective action unit 63 provides the user with the following three options (1) to (3). The user can select a countermeasure from the three options. Option (1) is to manually modify the recipe of the remaining tasks so as to meet the reserved time limit. Option (2) is to request the recipe proposal unit 25 to propose a recipe for the remaining tasks so as to meet the reserved time limit, assuming that sufficient time is available to perform the remaining tasks. Option (3) is to change the schedule such that the job is terminated midway (for example, when the job includes ten tasks, the job is stopped at task 8).

When the user is not responsible for the cause of the delay, the corrective action unit 63 provides the user with the following three options (1) to (3). The user can select a countermeasure from the three options. Option (1) is to manually modify the recipe of the remaining tasks so as to meet the reserved time limit. Option (2) is to request the recipe proposal unit 25 to propose a recipe for the remaining tasks so as to meet the reserved time limit. Option (3) is to complete the job later than the reserved time limit and notify, via the notification unit 64, the next user that a delay has occurred due to the measurement system 200. In this case, the schedule of the user's job is extended to part of the time slot scheduled for the next user. The next user is provided with the same options as the current user. The user may modify the schedule or measurement recipe according to the proposal from the corrective action unit 63, thereby limiting the effect on another user's job reserved in the next time slot.

### Hardware Configuration Example

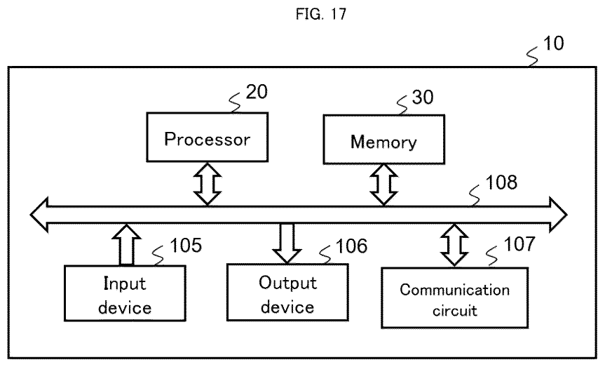

An example of the hardware configuration of the scheduling apparatus 10 is now described. FIG. 17 is a block diagram illustrating an example of the hardware configuration of the scheduling apparatus according to the embodiment. The scheduling apparatus 10 may be a server, for example. The scheduling apparatus 10 includes a processor 20, a memory 30, an input device 105, an output device 106, and a communication circuit 107. The processor 20, the memory 30, the input device 105, the output device 106, and the communication circuit 107 are connected to one another via a bus 108.

The processor 20 is an arithmetic apparatus such as a CPU, an MPU (Micro Processing Unit), or a GPU (Graphics Processing Unit). The memory 30 is a non-volatile memory. For example, the memory 30 may be a storage apparatus such as an HDD (Hard Disk Drive) or an SSD (Solid State Drive). The memory 30 stores a program in addition to the data described above. When the processor 20 executes the program, the functions of the information acquisition unit 1, the information analysis unit 2, the job time estimation unit 3, the scheduling unit 4, the report unit 5, and the error processing unit 6 shown in FIG. 1 are performed.

The input device 105 may be a keyboard, a mouse, or a touch panel, for example. The output device 106 may be a display or a speaker, for example. The communication circuit 107 transmits and receives data to and from other apparatuses via the external network 101 or the external network 102. For example, the communication circuit 107 transmits and receives data to and from other apparatuses in accordance with a communication protocol such as IP (Internet Protocol).

Some or all of the functions of the information acquisition unit 1, the information analysis unit 2, the job time estimation unit 3, the scheduling unit 4, the report unit 5, and the error processing unit 6 shown in FIG. 1 may be performed by a dedicated circuit such as an ASIC (Application Specific Integrated Circuit). The hardware configuration of the user terminal 7 is also similar to the example configuration shown in FIG. 17, and thus a detailed description thereof is omitted. FIG. 17 shows an example in which a user can directly operate the input device 105 of the scheduling apparatus 10 to input data, and the scheduling apparatus 10 can output the processing results to the output device 106. As such, when the user transmits data to the scheduling apparatus 10 via the user terminal 7 and acquires processing results from the scheduling apparatus 10, the scheduling apparatus 10 does not need to include the input device 105 or the output device 106.

### Description of Operation

A procedure is described in which a user causes the measurement apparatus 8 to measure a measurement target 100 by using the measurement system 200 of the present embodiment. The user operates the user terminal 7 to upload job information to the scheduling apparatus 10 via a web page, and input a desired schedule to the scheduling apparatus 10 via the web page. The control computer 83, which controls the SEM main body 81, is connected to the gateway server 9 via the private network 103. The gateway server 9 automatically collects data from the control computer 83 and uploads the collected data to the scheduling apparatus 10 to monitor the progress of the job.

An example of a procedure of measuring the measurement target 100 in the measurement apparatus 8 after the user inputs a measurement recipe into the scheduling apparatus 10 via the user terminal 7 is described.
(1) The user operates the user terminal 7 to upload job information to the scheduling apparatus 10 via a web page.
(2) The user operates the user terminal 7 to select a desired schedule via the web page.
(3) The user checks the tentative schedule proposed by the scheduling apparatus 10 and finalizes or changes the tentative schedule. When the user agrees to the tentative schedule, the scheduling apparatus 10 transmits the measurement recipe and schedule to the control computer 83.
(4) At the start time of the job, the user sets the measurement target 100 on the measurement apparatus 8 and starts measurement. The control computer 83 notifies the scheduling apparatus 10 of the start of the job. At this time, the user may input to the scheduling apparatus 10, either directly or remotely, information indicating that the job has started. Upon receiving the notification that the job has started, the scheduling apparatus 10 acquires an SEM output via the gateway server 9 and monitors the progress of the job.
(5) When a delay occurs in the job, the scheduling apparatus 10 provides the user with an option to modify the recipe so that the user can determine priorities among the remaining tasks to be performed.

Referring to FIGS. 18 and 19, the operation of the scheduling apparatus 10 of this embodiment is now described in detail. FIGS. 18 and 19 are flowcharts showing an example of an operation procedure of the scheduling apparatus of this embodiment.

At step S101, when a user uploads job information and a desired schedule, the job information and the desired schedule are input to the scheduling apparatus 10 via the information acquisition unit 1. At step S102, the recipe analysis unit 21 analyzes the measurement recipe and creates a task list on the basis of the analysis results. The scheduling apparatus 10 analyzes the information collected at step S101, converts the job into multiple tasks, and creates a task list to estimate the time required for each task.

At step S103, the related data identification unit 22 identifies related data needed to estimate the job time. In the task list created at step S102, some tasks among the series of tasks may require additional related data for estimating the time required for the task. For example, the related data may be apparatus information. A specific example in which the related data is apparatus information is described.

When the task is evacuation, the related data includes information such as the SEM model, the vacuum pump model, the sample material, and the required vacuum level Pr0. The SEM model is used to determine the chamber size. This is because, for an evacuation task, the internal volume of the container from which air is to be discharged is one of the important parameters. Some of those information pieces may not be input at step S101. The related data may not be input by the user at step S101, but may already be stored in the database 16, which contains history information such as log data. As such, at step S103, the related data identification unit 22 also scans the database 16.

At step S104, the data collection unit 23 collects related data necessary to update the ML model 32, which estimates the time required for each task. The related data may be collected from the database 16 or may be collected from outside. The automatic data collection unit 27 collects necessary related data from the database 16 by collection processing such as data mining. Examples of the data to be collected from the database 16 include apparatus information and setting information about the measurement apparatus 8, output information about the output of the measurement apparatus 8 and metafiles corresponding to the output information, and sample information. The manual data collection unit 28 may collect necessary related data from outside. For example, the related data to be collected may be advice of an expert studying the measurement target 100.

For example, after the stage 182 carrying the sample S moves at a movement speed V and then stops, a certain waiting time is required before the vibration of the stage is damped. When the sample S is a new material, the related data necessary to estimate the waiting time is preferably acquired with advice of an expert studying the new material. As related data necessary to estimate the time required for a series of tasks, one or more pieces of information selected from apparatus information, setting information, output information, metafiles, sample information, and expert advice are added. Information relating to the task is supplemented regarding the measurement apparatus 8 or the sample, thereby improving estimation accuracy.

At step S105, the data collection unit 23 determines whether the collected data is sufficient to update the ML model 32. This is because it is necessary to evaluate whether the collected data is sufficient to perform ML inference correctly. When determining that the collected data is insufficient, the data collection unit 23 creates a prompt requesting the user to input the missing data, and presents the created prompt to the user. Then, the data collection unit 23 proceeds to step S106. When determining that the collected data is sufficient, the data collection unit 23 proceeds to step S107.

At step S106, when the user uploads the missing data, the missing data is input to the data collection unit 23. For example, there may be a case in which the user inputs a vacuum pump model, but the apparatus information of the target vacuum pump model is not stored in the database 16. In this case, the ML inference unit 31 may not be able to estimate the time required for the task of evacuation because the ML inference unit 31 cannot identify the pumping speed. Thus, the data collection unit 23 requests the user to input the pumping speed or the average time required to complete the pumping.

At step S107, the ML model update unit 24 updates the ML model 32. The ML model 32 used for estimation is updated to fit the input task list 26 on the basis of the collected related data. The ML model update unit 24 updates the ML model 32 using the collected related data and history information used to train the ML model 32 in the past, and adjusts the ML model 32 in accordance with the target job. At step S108, the job time estimation unit 3 inputs information on a series of tasks into the ML model 32, causes the ML model 32 to execute ML inference, and acquires information on the estimated time required for each task. The job time calculation unit 41 obtains the estimated total job time by adding up the estimated time required for each task of a series of tasks.

At step S109, the schedule proposal unit 43 determines the optimal time slot for the current user on the basis of the estimated time required for each task, the estimated total job time, and information on time slots used by the user in the past. The report unit 5 provides the user with a job time report including information on the estimated time required for each task, a recipe report regarding the time required for the job, and an updated version of the measurement recipe.

At step S110, a report presenting a tentative schedule to the user is provided by the report unit 5 to the user. The schedule proposal unit 43 determines whether the user agrees to the tentative schedule. The user can select one of three options as a response to the presentation of the tentative schedule. The three options are that the user agrees to the tentative schedule, that the user changes the deadline and requests rescheduling, and that the user requests a new recipe proposal. Although not shown in FIG. 18, the user may manually modify the input recipe, return to step S101, and have the scheduling apparatus 10 restart the flow from the start.

If it is determined at step S110 that the user changes the deadline and requests rescheduling, the processor 20 returns to step S109. The processing in this case is the same as that described above, and therefore a detailed description thereof is omitted. If the result of the determination at step S110 is that the user does not agree to the tentative schedule and requests a new recipe, the processor 20 proceeds to step S111. For example, when the user thinks that the desired data cannot be acquired with the presented tentative schedule, the user requests the scheduling apparatus 10 to propose a new recipe.

At step S111, the recipe proposal unit 25 optimizes the recipe such that the job is completed within the time of the tentative schedule. The recipe proposal unit 25 evaluates the measurement conditions of the measurement recipe input by the user. When it is determined that there are conditions that can be changed, the recipe proposal unit 25 changes the identified conditions. When the recipe proposal unit 25 transmits the optimized recipe to the recipe analysis unit 21, the processor 20 returns to step S102. For example, the recipe proposal unit 25 transmits a newly created recipe that shortens the job time to the recipe analysis unit 21.

In contrast, if the result of the determination at step S110 is that the user agrees to the tentative schedule, the processor 20 proceeds to step S112. The report unit 5 verifies that the user agrees to the scheduled time slot and the job time report. When the job schedule and measurement recipe are finalized by the user agreeing to the tentative schedule, the schedule proposal unit 43 transmits information on the schedule and measurement recipe to the control computer 83. At the start time of the job, the user sets the measurement target 100 on the measurement apparatus 8 and starts measurement. The control computer 83 of the measurement apparatus 8 refers to the user's schedule and starts a job in accordance with the measurement recipe when a measurement instruction is input from the user. The control computer 83 notifies the scheduling apparatus 10 of the start of the job. At step S112, the error processing unit 6 recognizes that the execution of the job has started.

At step S113, the progress monitoring unit 61 monitors the progress of the job. At step S114, the performance monitoring unit 62 determines whether an error has occurred. The performance monitoring unit 62 compares the estimated required time tp with the actual required time tr. When these times match and no errors occur, the job is performed according to the measurement recipe to the end. If an error occurs in which the estimated required time tp is overestimated, or if the job is completed in the estimated required time, the error processing unit 6 proceeds to step S116. If an error occurs in which the estimated required time tp is underestimated, a delay occurs in the schedule, and therefore the error processing unit 6 proceeds to step S115.

At step S116, the corrective action unit 63 notifies the next user of the information that the job can be started earlier. The next user is given the option to start the job earlier and finish it earlier. At step S115, the corrective action unit 63 refers to the log data of the progress and determines whether the schedule delay is due to a user error. The corrective action unit 63 checks whether the delay is due to a user error or an incorrect estimation of the job time. An example of a user error is that the start of measurement is delayed from the schedule.

If the result of the determination at step S115 is that the delay is not due to a user error, the corrective action unit 63 sends log data indicating the progress of the job to the ML model update unit 24 to update the ML model 32. Specifically, the corrective action unit 63 reads log data indicating the progress of the job from the database 16 at a predetermined timing and transmits the log data to the ML model update unit 24. The predetermined timing may be a fixed cycle or when a task is switched, for example. At step S107, the ML model update unit 24 updates the ML model 32 on the basis of the log data. At step S108, each time the ML model 32 is updated, the ML inference unit 31 re-estimates, using the updated ML model 32, the time required for the remaining unperformed tasks of the series of tasks. In this case, while the job is being performed, the ML model 32, which estimates the time required for the task, is updated using the log data, and the time required for the remaining tasks is re-estimated. This improves the accuracy of prediction of the completion time of the job being performed.

If the result of the determination at step S115 is that the delay is not due to a user error, the corrective action unit 63 proceeds to step S121. At step S121, the corrective action unit 63 determines whether the user or the schedule has flexibility. Since the delay is not due to a user error, the user can select whether to assume responsibility. If the result of the determination at step S121 indicates flexibility sufficient for the user to modify the recipe or for the schedule to terminate the job early, the corrective action unit 63 proceeds to step S117.

In contrast, if the result of the determination at step S121 indicates that the user is not flexible and selects not to assume responsibility, the job will finish later than the time slot allocated to the user. When the next user's job is reserved for the next time slot, the job will conflict with the next user's job. When multiple users'jobs are scheduled in consecutive time slots, multiple users will be affected. For this reason, at step S122, the corrective action unit 63 notifies one or more users who will be affected by the delay of information that a delay has occurred.

The corrective action unit 63 identifies users who will be affected by the delay, and notifies the identified users of information indicating that the ML model 32, which estimates job time, is to be updated. This is because the measurement recipe of the user who will be affected by the delay may contain a task with an estimation error. In this case, the ML model update unit 24 updates the ML model 32 as described above. The scheduling unit 4 uses the estimated total job time calculated based on the updated ML model 32 to change the desired schedule of the user who will be affected by the delay. Alternatively, the corrective action unit 63 may provide the user who will be affected by the delay with an opportunity to modify the recipe.

In contrast, if the result of the determination at step S115 is that the delay is due to a user error, the corrective action unit 63 proceeds to step S117. At step S117, the corrective action unit 63 determines whether the user accepts a modification to the recipe. The user can select whether to continue the job and terminate it midway before the remaining tasks are completed (step S118), or to modify the recipe such that some of the remaining tasks are not performed (step S120).

When the result of the determination at step S117 is that the user does not accept a modification to the measurement recipe, the corrective action unit 63 terminates the job midway (step S118). This is to prevent the delayed job from conflicting with the next reserved job of another user. The job currently being performed terminates without performing some of the tasks in the series of tasks.

In contrast, if the result of the determination at step S117 is that the user accepts a modification to the measurement recipe, the corrective action unit 63 asks the user whether to request a proposal for a new measurement recipe (step S119). The user can select whether to manually modification the measurement recipe to fit the schedule, or select a recipe optimization tool (step S111) to request a new measurement recipe proposal. If, as the result of the determination at step S119, the measurement recipe is manually modified by the user (step S120), the corrective action unit 63 returns to step S102 and transmits the modified measurement recipe to the recipe analysis unit 21. In contrast, if, as the result of the determination at step S119, a proposal for a new recipe is requested by the user, the corrective action unit 63 requests the recipe proposal unit 25 to optimize the measurement recipe (step S111).

### Example of Input Operation Image

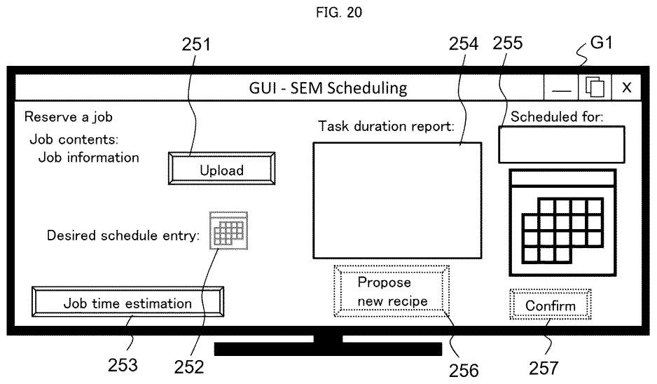

Referring to FIGS. 20 to 22, specific examples of input operation images output on the output device 106 of the user terminal 7 by the information acquisition unit 1 are now described. FIGS. 20 to 22 show examples of graphical user interface (GUI) images for schedule input. An example in which the output device 106 is a display is described.

FIG. 20 is a diagram showing an example of an input image displayed on the output device at step S101 shown in FIG. 18. At step S101 shown in FIG. 18, the user terminal 7 displays the input image shown in FIG. 20 on the output device 106. The user clicks an upload button 251 while referring to the input image G1 to upload job information. The user also clicks on a calendar icon 252 displayed next to the item of “Desired schedule entry” to input the date of the desired schedule. The user then clicks on a job time estimation button 253. As a result, the scheduling apparatus 10 proceeds to step S102.

At the stage of step S101, since the schedule has not been determined, nothing is displayed in a task duration report display field 254 and a schedule display field 255 of the input image G1. Also, in FIG. 20, a request button 256, which is to be selected by the user when requesting a new recipe proposal, is indicated by a broken line because it cannot be selected by the user at the stage of step S101. A confirmation button 257, which is to be selected after the user checks a tentatively determined schedule, is also indicated by a broken line because it cannot be selected by the user at the stage of step S101.

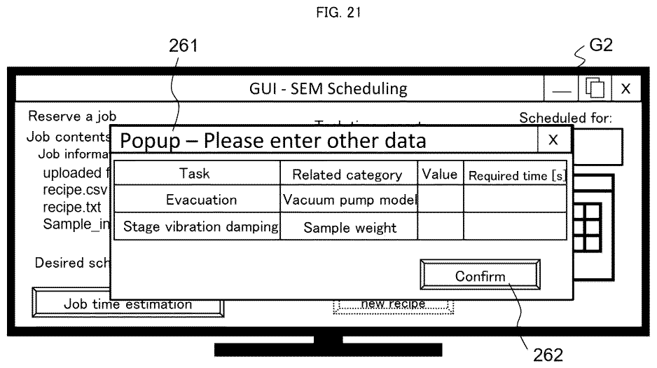

FIG. 21 is a diagram showing an example of an input image displayed on the output device when it is determined at step S105 shown in FIG. 18 that there is missing data. At step S102 shown in FIG. 18, the recipe analysis unit 21 analyzes the measurement recipe. At step S103, the related data identification unit 22 determines, based on the job information and the data available in the database 16, whether there is any other related data necessary to update the ML model 32. When there is necessary related data, at step S105, the data collection unit 23 causes the user terminal 7 to display a pop-up image requesting additional data.

In one example of a pop-up image, as shown in FIG. 21, a pop-up image 261 is displayed on the output device 106 requesting the user to add other data. As shown in the input image G2, the pop-up image 261 is displayed over the input image G1 shown in FIG. 20. In the example shown in FIG. 21, other data that needs to be input is data relating to two tasks of “evacuation” and “stage vibration damping.” When the task is “evacuation,” input of a vacuum pump model value and required time is requested. The vacuum pump model is specified by a value such as “A353.” The required time is the time from when evacuation of the vacuum chamber 181 starts until the pressure in the vacuum chamber 181 reaches the vacuum level Pr0. When the task is “stage vibration damping,” input of a sample weight value and required time is requested. The sample weight may be a value such as “30 g,” for example. The required time is the waiting time between when the stage 182 stops moving and when the vibration of the stage 182 is damped.

When the user knows the value and required time for each of the above two tasks, the user inputs this data via the input device 105. After inputting this data, the user clicks the confirmation button 262. The user terminal 7 transmits the data input by the user as other data to the scheduling apparatus 10.

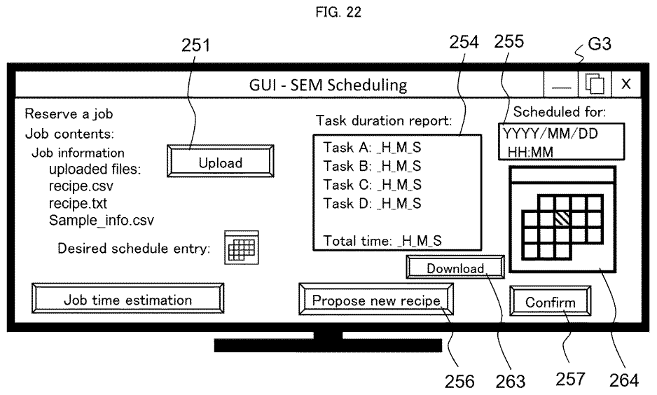

FIG. 22 is a diagram showing an example of an input image displayed on the output device at step S110 shown in FIG. 18. The input image G3 of FIG. 22 shows the result of the schedule proposed by the scheduling unit 4. The task duration report display field 254 displays the time required for each of tasks A to D “H_M_S” and the total time of the time required for the series of tasks “H_M_S.” The schedule display field 255 shows that the start of the measurement job is scheduled at “YYYY/MM/DD HH:MM.” When the user operates the input device 105 to click the download button 263, the task required time report can be downloaded from the scheduling apparatus 10 to the memory 30 of the user terminal 7. In a calendar 264, the date “MM/DD” on which the measurement job is scheduled is indicated with a hatched pattern.

At step S110 shown in FIG. 18, when the input image G3 shown in FIG. 22 is displayed, the user can select one of three options. The first option is for the user to check the displayed schedule and, if the schedule is agreeable, click on the confirmation button 257. The second option is for the user to click on the request button 256, if the user requests a new recipe proposal. The third option is for the user to change the input information, including the job information and desired schedule, if the user is dissatisfied with the displayed schedule. For the third option, the user can click on an upload button 251 to upload the changed input information.

### Monitoring Image Example

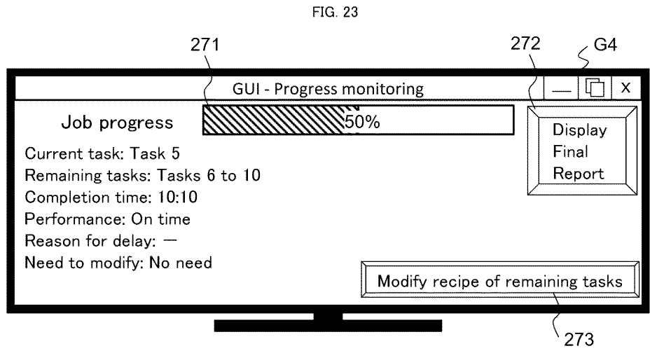

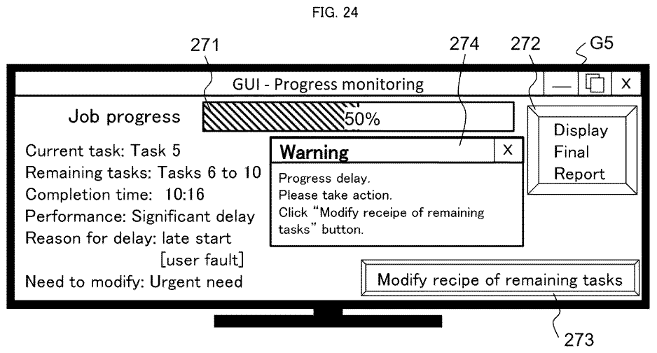

Referring to FIGS. 23 and 24, specific examples of monitoring images output on the output device 106 of the user terminal 7 by the progress monitoring unit 61 are now described. FIGS. 23 and 24 show examples of GUI images showing the progress of a measurement job.

FIG. 23 is a diagram showing an example of a monitoring image in a state in which the job is in progress according to schedule. In the monitoring image G4, a progress graph 271 is displayed in which the progress of the job is represented by the length of a bar. The user can check the progress of the job by referring to the progress graph 271. The progress graph 271 shown in FIG. 23 indicates that the job is half complete.

Additionally, the monitoring image G4 displays an overview of the job progress. Specifically, information is displayed regarding the current task, the remaining tasks, the completion time, performance, the reason for delay, and the necessity for modification. By referring to the monitoring image G4, the user can identify the task currently being performed, the remaining tasks, the completion time, whether the progress is on schedule, and whether a delay has occurred. By comparing the job progress outline with the estimated job completion time, the user can determine whether the job is properly in progress. With the monitoring image G4, the job is in progress according to schedule, so the performance field states “On time” and the necessity for recipe modification field states “No need.”

Additionally, the user can check the final report by clicking a “Display Final Report” button 272 displayed on the monitoring image G4. The user may refer to the displayed final report and change the measurement recipe. At any time within the scheduled time, the user can modify the recipe for the remaining tasks to increase or decrease the job time by clicking a recipe modification button 273 indicating “Modify recipe of remaining tasks.”

FIG. 24 is a diagram showing an example of a monitoring image in a state in which the progress of a job is behind schedule. For the monitoring image G5, since the progress of the job is behind schedule, the performance field indicates “Significant delay” and the necessity for recipe modification field indicates “Urgent need.” In addition, the reason for delay field indicates “late start (user fault).” With the monitoring image G5, it can be seen that the job will not be completed on schedule due to a user error.

When a job of a different user is reserved after the job being performed and the job being performed does not complete within the scheduled time, it is not possible to start the job of the different user as scheduled. For this reason, a warning image 274 is displayed as in the monitoring image G5 of FIG. 24. As shown in the prompt in the warning image 274, the user is asked to “Modify recipe of remaining tasks.” In response to this warning, the user can click on the recipe modification button 273 to modify the recipe for the remaining tasks 6 to 10 so that the job completes within the scheduled time. For example, the user can cause the high-priority tasks 6, 9, and 10 to be performed by modifying the recipe to skip tasks 7 and 8 among the remaining tasks 6 to 10. In contrast, when the user ignores the warning, the corrective action unit 63 terminates the job midway (see step S118 shown in FIG. 19). For example, the corrective action unit 63 terminates the job without performing two tasks 9 and 10 of the remaining tasks 6 to 10.

In this embodiment, the scheduling apparatus 10 is a scheduling apparatus that estimates time of a measurement job to be performed by the measurement apparatus 8, and includes the memory 30 that stores a program and the processor 20 that executes processing in accordance with the program. The processor 20 operates as follows by executing the program. When a measurement recipe for causing the measurement apparatus 8 to perform a measurement job is input by a user, the processor 20 analyzes the measurement recipe and creates a series of tasks on the basis of a result of the analysis. The processor 20 collects information for updating the estimation model that estimates the time required for the measurement job. The processor 20 updates the estimation model using the collected information. The processor 20 estimates the time required for the series of tasks on the basis of the updated estimation model.

According to this embodiment, a user's measurement recipe is analyzed, and time required for the measurement job is estimated by the estimation model updated using the collected information, on the basis of the series of tasks obtained by converting the measurement recipe. Accordingly, even for a measurement job whose required time is difficult to predict or for samples having large variation in measurement time, the time required for the measurement job can be accurately estimated. As a result, the measurement job is performed as desired by the user, and the measurement schedule is configured such that the operating rate of the measurement apparatus is maximized. This improves the utilization rate of the measurement apparatus 8. Furthermore, when the measurement apparatus 8 is shared equipment used by multiple users, the multiple users can efficiently use the measurement apparatus 8.

The scheduling apparatus 10 according to this embodiment can achieve a high utilization rate of the measurement apparatus 8, such as an SEM, through scheduling using an advanced job time estimation technology. In this embodiment, ML is used to estimate job time. To use ML to estimate job time, the scheduling apparatus 10 in this embodiment includes the information analysis unit 2 that analyzes a measurement recipe and creates a task list 26, and the job time estimation unit 3 that causes the ML model 32 to estimate a duration of each task. This allows for accurate job time estimation, making it possible to schedule more jobs than with a conventional configuration. As a result, the utilization rate of the measurement apparatus 8 is improved. This not only accelerates the acquisition of measurement results but also allows the measurement apparatus 8 to be shared more efficiently among users. In particular, since the target market segments of this embodiment include various market segments in which an SEM needs to be shared, scheduling of the SEM is necessary.

The first market segment is research and development departments (for example, development of new materials for batteries) of material companies. In the first market segment, the level of need for the scheduling apparatus 10 of the present embodiment is high. The reason is as follows. Multiple jobs (for example, experiments and tests) are needed, and the types of materials vary. That is, since the job time differs for each material depending on the measurement recipe, a simple job time estimation algorithm for scheduling is insufficient. Accordingly, rapid acquisition of results is required, and the measurement apparatus needs to be used in accordance with the schedule. Thus, this embodiment is necessary also to realize full laboratory automation. Without the scheduling apparatus 10 of the present embodiment, the provision of results may be delayed, deadlines may be missed, and full automation may not be supported.

The second market segment is material analysis centers. In the material analysis centers, the level of need for the scheduling apparatus 10 of the present embodiment is lower than that in the first market segment. The material analysis center handles a large volume of work and various types of materials, so that the measurement apparatus 8 is expected to provide results quickly. It is thus necessary to use the measurement apparatus 8 efficiently. Without the present embodiment, the measurement apparatus 8 cannot be used efficiently, resulting in longer wait times for clients to obtain results, slower measurement cycles, and reduced profits.

The third market segment is universities. In universities, the level of need for the scheduling apparatus 10 of this embodiment is lower than that of the second market segment. Although universities handle various materials, traffic is low, the utilization rate of the measurement apparatus 8 is high, and lab automation is not mandatory. Even without the scheduling apparatus 10 of this embodiment, the loss is not significant because traffic is low and rapid measurement is not highly required.

The fourth market segment is the material industry. In the material industry, the level of need for the scheduling apparatus 10 of this embodiment is lower than that of the second market segment. Although the material industry has high job traffic and strict deadlines, and requires a high utilization rate of the measurement apparatus 8 and full laboratory automation, the same materials are usually handled, and the variety of materials is limited. As such, a simple job time estimation algorithm is sufficient, and there is no significant loss even if the scheduling apparatus 10 of this embodiment is not used.

The above-described embodiments are examples for illustrating the present invention, and are not intended to limit the scope of the present invention to only those embodiments. Those skilled in the art can implement the present invention in various other forms without departing from the scope of the present invention.

The above-described embodiments also include the following items. However, the items included in the embodiments are not limited to those listed below.

### Item 1

A scheduling apparatus for estimating time of a measurement job to be performed by a measurement apparatus, the scheduling apparatus including:
a memory configured to store a program; and
a processor configured to perform processing in accordance with the program, in which
the processor is configured, by executing the program, to:
in response to a user inputting a measurement recipe for causing the measurement apparatus to perform the measurement job, analyze the measurement recipe and create a series of tasks on the basis of an analysis result;
collect information for updating an estimation model that estimates time required for the measurement job;
update the estimation model using the collected information; and
input information on the series of tasks into the updated estimation model to estimate time required for the series of tasks.

According to the above, a user's measurement recipe is analyzed, and time required for the measurement job is estimated by the estimation model updated using the collected information, on the basis of the series of tasks obtained by converting the measurement recipe. Accordingly, even for a measurement job whose required time is difficult to predict or for samples having large variation in measurement time, the time required for the measurement job can be accurately estimated. As a result, the measurement job is performed as desired by the user, and the measurement schedule is configured such that the operating rate of the measurement apparatus, such as an SEM, is maximized. This improves the utilization rate of the measurement apparatus. Furthermore, when the measurement apparatus is shared equipment used by multiple users, the multiple users can efficiently use the measurement apparatus.

### Item 2

The scheduling apparatus according to item 1, in which the processor is configured to
acquire as the collected information, data of one or more of apparatus information about the measurement apparatus, setting information for the measurement apparatus, output information about output of the measurement apparatus, a metafile corresponding to the output information, sample information about a measurement target, and advice of an expert on the measurement target.

According to the above, for the estimation of the time required for a series of tasks, one or more pieces of information selected from apparatus information, setting information, output information, metafiles, sample information, and expert advice are added. Information relating to the task is supplemented regarding the measurement apparatus or the sample, thereby improving estimation accuracy.

### Item 3

The scheduling apparatus according to item 2, in which when the measurement apparatus is a scanning electron microscope,
the processor is configured to
cause an autofocus speed, a stage movement speed, and stage vibration damping time to be reflected in the estimation model as the apparatus information.

According to the above, since the apparatus information of the scanning electron microscope (SEM) is reflected in the estimation model, the estimation model can estimate job time for any SEM model.

### Item 4

The scheduling apparatus according to any one of items 1 to 3, in which
when a number of samples of a measurement target of the measurement job is plural, the series of tasks includes the tasks differing for respective ones of the plurality of the samples, and
the processor is configured to
use the estimation model to estimate time required for the tasks for each of the plurality of samples.

Consider a state in which the number of samples to be measured in one measurement job is two. For example, the two samples differ in structure or film thickness. In this case, since the time required for autofocus differs between the two samples, two tasks with different estimated required times are provided in the series of tasks. This improves the accuracy of estimating the total time required for a measurement job including tasks for measuring different samples.

### Item 5

The scheduling apparatus according to any one of items 1 to 4, in which
the processor is configured to
before updating the estimation model, perform at least one preprocessing among log data analysis, missing data supplementation, data classification, and filtering on the collected information.

According to the above, by performing preprocessing such as filtering before updating the estimation model, the estimation accuracy of the updated estimation model is improved.

### Item 6

The scheduling apparatus according to any one of items 1 to 5, in which
the processor is configured to
when the measurement job is not completed within estimated time, propose to the user another measurement recipe different from the input measurement recipe.

According to the above, apart from the measurement recipe being performed, another recipe that will complete the measurement job being performed within the estimated time is proposed to the user. By completing the measurement job being performed within the scheduled time, even when a measurement job of a different user is reserved after the measurement job being performed, the measurement job of the different user can start as scheduled.

### Item 7

The scheduling apparatus according to any one of items 1 to 6, in which
the memory is configured to store log data indicating progress of the measurement job while the measurement job is being performed, and
the processor is configured to
while the measurement job is being performed, read the log data from the memory at a predetermined timing, update the estimation model on the basis of the read log data, and each time the estimation model is updated, re-estimate time required for remaining unperformed tasks among the series of tasks.

According to the above, while the measurement job is being performed, the ML model that estimates the time required for tasks is updated using log data, and the time required for the remaining tasks is re-estimated. This improves the accuracy of prediction of the completion time of the measurement job being performed.

### Item 8

The scheduling apparatus according to any one of items 1 to 7, in which
the processor is configured to
acquire, as the collected information, training data from an external server coupled via a network, and
update the estimation model on the basis of the acquired training data.

According to the above, the estimation model is updated using training data from an external server, thereby improving the accuracy of estimating the time required for a measurement job even when the measurement target is a new material sample that has never been measured before.

### Item 9

The scheduling apparatus according to any one of items 1 to 8, in which
the processor is configured to
in accordance with contents of the measurement recipe, add time of safety margin of error to estimated time required for the series of tasks.

According to the above, by adding time of a safety margin of error to the estimated time required for a series of tasks in accordance with the contents of the measurement recipe, it is possible to prevent a job from being forcibly terminated midway due to a minor operational error.

### Item 10

The scheduling apparatus according to any one of items 1 to 9, in which
the processor is configured to
in response to an error occurring while the measurement job is being performed, propose the user a change to a schedule of the measurement job, and, in response to a delay occurring in the measurement job due to the user, propose the user a modification to the measurement recipe.

According to the above, when an error occurs in the measurement job being performed, a proposal is made to the user to change the schedule or the measurement recipe. The user may change the schedule or measurement recipe according to the proposal, thereby limiting the effect on another user's job reserved in the next time slot.

What is claimed is:

1. A scheduling apparatus for estimating time of a measurement job to be performed by a measurement apparatus, the scheduling apparatus comprising:
a memory configured to store a program; and
a processor configured to perform processing in accordance with the program, wherein
the processor is configured, by executing the program, to:
in response to a user inputting a measurement recipe for causing the measurement apparatus to perform the measurement job, analyze the measurement recipe and create a series of tasks on the basis of an analysis result;
collect information for updating an estimation model that estimates time required for the measurement job;
update the estimation model using the collected information; and
input information on the series of tasks into the updated estimation model to estimate time required for the series of tasks.

2. The scheduling apparatus according to claim 1, wherein
the processor is configured to
acquire as the collected information, data of one or more of apparatus information about the measurement apparatus, setting information for the measurement apparatus, output information about output of the measurement apparatus, a metafile corresponding to the output information, sample information about a measurement target, and advice of an expert on the measurement target.

3. The scheduling apparatus according to claim 2, wherein
when the measurement apparatus is a scanning electron microscope,
the processor is configured to
cause an autofocus speed, a stage movement speed, and stage vibration damping time to be reflected in the estimation model as the apparatus information.

4. The scheduling apparatus according to claim 1, wherein
when a number of samples of a measurement target of the measurement job is plural, the series of tasks includes the tasks differing for respective ones of the plurality of the samples, and
the processor is configured to
use the estimation model to estimate time required for the tasks for each of the plurality of samples.

5. The scheduling apparatus according to claim 1, wherein
the processor is configured to
before updating the estimation model, perform at least one preprocessing among log data analysis, missing data supplementation, data classification, and filtering on the collected information.

6. The scheduling apparatus according to claim 1, wherein
the processor is configured to
when the measurement job is not completed within estimated time, propose to the user another measurement recipe different from the input measurement recipe.

7. The scheduling apparatus according to claim 1, wherein
the memory is configured to store log data indicating progress of the measurement job while the measurement job is being performed, and
the processor is configured to
while the measurement job is being performed, read the log data from the memory at a predetermined timing, update the estimation model on the basis of the read log data, and
re-estimate, each time the estimation model is updated, time required for remaining unperformed tasks among the series of tasks.

8. The scheduling apparatus according to claim 1, wherein
the processor is configured to
acquire, as the collected information, training data from an external server coupled via a network, and
update the estimation model on the basis of the acquired training data.

9. The scheduling apparatus according to claim 1, wherein
the processor is configured to
in accordance with contents of the measurement recipe, add time of safety margin of error to estimated time required for the series of tasks.

10. The scheduling apparatus according to claim 1, wherein
the processor is configured to
in response to an error occurring while the measurement job is being performed, propose the user a change to a schedule of the measurement job, and, in response to a delay occurring in the measurement job due to the user, propose the user a modification to the measurement recipe.

11. A scheduling method to be performed by an information processing apparatus that estimates time of a measurement job to be performed by a measurement apparatus, the method comprising:
in response to a user inputting a measurement recipe for causing the measurement apparatus to perform the measurement job, analyzing the measurement recipe and creating a series of tasks on the basis of an analysis result;
collecting information for updating an estimation model that estimates time required for the measurement job;
updating the estimation model using the collected information; and
inputting information on the series of tasks into the updated estimation model to estimate time required for the series of tasks.

12. A non-transitory computer readable medium storing a program for causing a computer that estimates time of a measurement job to be performed by a measurement apparatus to:
in response to a user inputting a measurement recipe for causing the measurement apparatus to perform the measurement job, analyze the measurement recipe and create a series of tasks on the basis of an analysis result;
collect information for updating an estimation model that estimates time required for the measurement job;
update the estimation model using the collected information; and
input information on the series of tasks into the updated estimation model to estimate time required for the series of tasks.
